(19) United States
(12) Patent Application Publication
(10) Pub. No.: US 2026/0185223 A1
(43) Pub. Date: Jul. 2, 2026

(54) METHODS OF FORMING A METAL, PHOSPHORUS, AND NITROGEN LAYER STRUCTURES ON A SUBSTRATE, AND THRESHOLD VOLTAGE SHIFTING LAYERS INCLUDING A METAL, PHOSPHORUS, AND NITROGEN LAYER STRUCTURE

(71) Applicant: ASM IP Holding B.V., Almere (NL)

(72) Inventors: Petro Deminskyi, Espoo (FI); Hoang Minh Nguyen, Espoo, Uusima (FI); Mikko Leander Nisula, Espoo (FI); Michael Eugene Givens, Scottsdale, AZ (US); Andrea Illiberi, Gilbert, AZ (US); Jian-Wei Liang, Scottsdale, AZ (US); Vivek Koladi Mootheri, Leuven (BE); Ren-Jie Chang, Chandler, AZ (US); Giuseppe Alessio Verni, Ismaning (DE)

(21) Appl. No.: 19/432,291

(22) Filed: Dec. 24, 2025

Related U.S. Application Data
(60) Provisional application No. 63/739,184, filed on Dec. 27, 2024.

(51) Int. Cl. C23C 16/455; C23C 16/30; C23C 16/34; H10D 64/01; H10P 14/43

(52) U.S. Cl. CPC C23C 16/45531; C23C 16/30; C23C 16/34; C23C 16/45529; C23C 16/45553; H10D 64/013; H10P 14/43

(57) ABSTRACT

Methods of forming metal, phosphorus, and nitrogen layer structures are disclosed. The methods include performing one or more deposition cycles of an atomic layer deposition process including introducing a metal precursor, and a phosphorus precursor. Methods of forming threshold voltage shifting layers comprising metal, phosphorus, and nitrogen layer structures are further disclosed.

### CROSS-REFERENCE TO RELATED APPLICATIONS

This application claims priority to U.S. Provisional Patent Application Ser. No. 63/739,184 filed Dec. 27, 2024 titled METHODS OF FORMING A METAL, PHOSPHORUS, AND NITROGEN LAYER STRUCTURES ON A SUBSTRATE, AND THRESHOLD VOLTAGE SHIFTING LAYERS INCLUDING A METAL, PHOSPHORUS, AND NITROGEN LAYER STRUCTURE, the disclosure of which is hereby incorporated by reference in its entirety.

### FIELD

The present disclosure relates generally to the field of semiconductor processing methods, and associated structures and to the field of device and integrated circuit manufacture. More particularly the present disclosure generally relates to metal, phosphorus, and nitrogen layer structures, as well as methods for forming said layer structures and to structures comprising said layer structures.

### BACKGROUND

The scaling of semiconductor devices, such as, for example, complementary metal-oxide-semiconductor (CMOS) devices, has led to significant improvements in the speed and density of integrated circuits. Further scaling of device dimensions for next generation nodes, however, is challenging and will require the use of alternative materials and new processing techniques. For example, one challenge has been finding suitable dielectric stacks that form an insulating barrier between a gate and a channel of a field effect transistor. As scaling continues, the reduced dimensions of the gate cavity will only allow for thin layers of dielectric stack materials, including threshold voltage shifting materials, liner materials, and the like. Thus, methods for achieving very thin layers and layer structures of novel materials for threshold voltage shifting and liners are of a high interest. The present disclosure addresses and meets these needs.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to method of forming metal, phosphorus, and nitrogen layer structures by atomic layer deposition processes. In particular examples, the metal, phosphorus, and nitrogen layer structures may be utilized as threshold voltage shifting layers as a part of a gate stack of a metal-oxide-semiconductor field effect transistor (MOSFET). The metal, phosphorus, and nitrogen layer structures provided can include metal and phosphorous containing layers and/or metal, phosphorus, and nitrogen containing layers having a low electrical resistivity, as well as a compatible effective work function (eWF) at low layer thicknesses. In addition, the metal and phosphorous containing layers and/or metal, phosphorus, and nitrogen containing layers provided can exhibit low resistivity and/or a suitable eWF when deposited at low deposition temperatures, such as, for example, below deposition temperatures of 400° C.

In accordance with examples of the disclosure a method of forming a metal, phosphorus, and nitrogen layer structure on a substrate is disclosed, the method comprising: seating the substrate within a reaction chamber, forming a surface layer on the substrate, and performing an atomic layer deposition process comprising a plurality of repeated deposition cycles. In accordance with examples of the disclosure, each deposition cycle can comprise: introducing a first metal precursor into the reaction chamber thereby forming a plurality of metal species on the surface of the substrate, and introducing a phosphorus precursor into the reaction chamber wherein the phosphorus precursor reacts with the plurality of metal species.

In some embodiments, the surface layer comprises a metal nitride surface layer deposited by an initial atomic layer deposition process comprising, sequentially and alternately introducing a second metal precursor and a nitrogen precursor into the reaction chamber.

In some embodiments, the second metal precursor comprises an initial metal halide precursor and the metal nitride surface layer comprises a halide rich surface.

In some embodiments, one or more of the deposition cycles further comprises, introducing an additional nitrogen precursor into the reaction chamber.

In some embodiments, the atomic layer deposition process is performed at substrate temperature between 200° C. and 400° C.

In some embodiments, the phosphorus precursor is selected from the group consisting of phosphine (PH₃), tetraphosphorus (P₄), 1,2-diphosphinoethane (C₂H₈P₂), methyl phosphine (PH₂Me), trimethyl phosphine (PMe₃), ethyl phosphine (PH₂Et), triethyl phosphine (PEt₃), isopropylphosphine (PH₂ⁱPr), i-butylphosphine (PH₂ⁱBu), t-butylphosphine (PH₂^{t}Bu), dichloromethylphosphine (MePCl₂), dichloroethylphosphine (PCl₂Et), dichloropropylphosphine (PCl₂ⁿPr), dichloroisopropylphosphine (PCl₂ⁱPr), dichlorobutylphosphine (PCl₂ⁿBu), dichlorotertbutylphosphine (PCl₂^{t}Bu), (PClⁱPr₂), chloro(dimethyl)phosphine (PClMe₂), chloro(diethyl)phosphine (PClEt₂), chloro(di-secbutyl)phosphine (PCl^{s}Bu₂), bromo(di-secbutyl)phosphine (PBr^{t}Bu₂), chloro(di-tertbutyl)phosphine (PCl^{t}Bu₂), chloro(tertbutyl)(methyl)phosphine (PCl^{t}BuMe), cyclohexylphosphine (PH₂(C₆H₁₁), phenyl phosphine (PH₂Ph), 1,2-diphosphinobenzene, tris(N-pyrrolidinyl)phosphine, dimethylaminophosphine (PH₂(NMe₂)₂), bis(dimethylamino)phosphine (PH(NMe₂), dimethylamino(methyl)phosphine(PMe(NMe₂)₂), tris(dimethylamino)phosphine (P(NMe₂)₃), tris(diethylamino)phosphine (P(NEt₂)₃), chlorobis(dimethylamino)phosphine (PCl(NMe₂)₂), dichloro(dimethylamino)phosphine (PCl₂(NMe₂)), dichloro(diethylamino)phosphine (PCl₂(NEt₂)), chlorobis(diethylamino)phosphine (PCl(NEt₂)₂), chlorobis(diisopropylamino)phosphine (PCl(NⁱPr₂)₂), dichloro(diisopropylamino)phosphine (PCl₂(NiPr₂)), tris(dimethylamino)phosphine (P(═NH)(NMe₂)₃), trisilylphosphine (P(SiH₃)₃), tris(trimethylsilyl) phosphine (P(SiMe₃)₃), tris(triethylsilyl) phosphine (P(SiEt₃)₃), tris(trimethylsiloxy)phosphine (P(OSiMe₃)₃), trimethyl phosphite (POMe₃), trimethyl phosphate (P(O)OMe₃), phosphorus pentoxide (P₂O₅), phosphorous trichloride (PCl₃), phosphorous tribromide (PBr₃), phosphorous triiodide (PI₃), phosphorous pentachloride (PCl₅), phosphorous pentabromide (PBr₅), phosphoryl chloride (POCl₃), and phosphoryl bromide (POBr₃) and combinations thereof.

In accordance with examples of the disclosure an atomic layer deposition process for depositing a metal, phosphorus, and nitrogen layer structure on a substrate seated within a reaction chamber is disclosed, the atomic layer deposition process comprising, performing one or more nitride sub-cycles, each of the one or more nitride sub-cycles comprising, contacting the substrate with a first metal halide precursor and contacting the substrate with a nitrogen precursor; and performing one or more phosphide sub-cycles, each of the one or more phosphide sub-cycles comprising, contacting the substrate with a phosphorus precursor;

In some embodiments, the metal, phosphorus, and nitrogen layer structure comprises one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

In some embodiments, the atomic layer deposition process is a super-cycle deposition process comprising performing one or more deposition super-cycles, each deposition super-cycle comprising one or more nitride sub-cycles and one or more phosphide sub-cycles.

In some embodiments, the metal, phosphorus, and nitrogen layer structure comprises one or more metal phosphorus nitride layers.

In some embodiments, each one of the phosphide sub-cycles further comprises contacting the substrate with a second metal halide precursor.

In some embodiments, each of the one or more deposition super-cycle comprises initially performing one or more nitride sub-cycles and subsequently performing one or more metal phosphide sub-cycles.

In some embodiments, the metal, phosphorus, and nitrogen layer structure comprises a metal nitride-metal phosphide laminate structure comprising a repeating unit layer structure comprising a metal nitride layer and a metal phosphide layer, the metal phosphide layer being disposed directly on the metal nitride layer.

In some embodiments, the first metal halide precursor comprises a first metal species (M₁) and the second metal halide precursor comprises a second metal species (M₂) different to the first metal species.

In some embodiments, the phosphorus precursor comprises an alkylphosphine, having the formula RₓPH₃₋ₓ, where x ranges from zero to 3 and R is an alkyl selected from the group consisting of ethyl, methyl, butyl, and propyl. In some embodiments, the alkylphosphine is selected from the group consisting of diethylphosphine, triethylphosphine, dimethylphosphine, trimethylphosphine, and mixtures thereof.

In some embodiments, the sub-cycle ratio (N₁:N₂) of the number (N₁) of repetitions of the nitride sub-cycle relative to the number (N₂) of repetitions of the phosphide sub-cycle is varied to control the composition of the metal, phosphorus, and nitrogen layer structure, the sub-cycle ratio (N₁:N₂) being equal to or greater than 1:1.

In some embodiments, the metal, phosphorus, and nitrogen layer structure is deposited at a substrate temperature between 250° C. and 400° C.

In accordance with examples of the disclosure a method of forming at least a portion of a gate stack for a semiconductor device structure is disclosed, the method comprising: seating a substrate within a reaction chamber, the substrate comprising a plurality of partially fabricated device structures, wherein one or more of the partially fabricated device structures includes a surface layer comprising a high-k dielectric layer or a silicon oxide surface. In accordance with examples of the disclosure the method further comprises performing one or more deposition super-cycles of an atomic layer deposition process to deposit a metal, phosphorus, and nitrogen layer structure directly on a surface of the high-k dielectric layer or the silicon oxide surface, wherein the metal, phosphorus, and nitrogen layer structure comprises a threshold voltage shifting layer and the metal, phosphorus, and nitrogen layer structure comprises one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

In some embodiments, one or more the deposition super-cycles comprises: performing one or more nitride sub-cycles, each of the one or more nitride sub-cycles comprising: contacting the substrate with a first metal halide precursor and contacting the substrate with a nitrogen precursor; and performing one or more phosphide sub-cycles, each of the one or more phosphide sub-cycles comprising: contacting the substrate with a second metal precursor and contacting the substrate with a phosphorus precursor.

In some embodiments, the threshold voltage shifting layer comprises a metal nitride-metal phosphide laminate structure selected from the group consisting of a titanium nitride-titanium phosphide laminate structure, a molybdenum nitride-molybdenum phosphide laminate structure, and a cobalt nitride-cobalt phosphide laminate structure.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

A more complete understanding of the embodiments of the present disclosure may be derived by referring to the detailed description and claims when considered in connection with the following illustrative figures.

FIG. 1 illustrates an atomic layer deposition process for forming a metal, phosphorus, and nitrogen layer structure in accordance with one or more embodiments.

FIGS. 2-4 illustrates schematic views of structures employed in the formation of metal, phosphorus, and nitrogen layer structures in accordance with one or more embodiments.

FIG. 5 illustrates an additional atomic layer deposition process for forming a metal, phosphorus, and nitrogen layer structure in accordance with one or more embodiments.

FIG. 6 illustrates a schematic view of a structure including a substrate and a metal and nitrogen containing layer in accordance with one or more embodiments.

FIG. 7 illustrates a schematic view of a structure including a substrate and a metal, phosphorus, and nitrogen layer structure in accordance with one or more embodiments.

FIG. 8 illustrates a further structure including a substrate and a metal, phosphorus, and nitrogen layer structure in accordance with one or more embodiments.

FIG. 9 illustrates a super-cycle deposition process for forming a metal, phosphorus, and nitrogen layer structure in accordance with one or more embodiments.

FIGS. 10-13 illustrates schematic views of additional structures employed in the formation of metal, phosphorus, and nitrogen layer structures in accordance with one or more embodiments.

FIG. 14 illustrates a method for forming at least a portion of a gate stack for a semiconductor device structure in accordance with one or more embodiments.

FIGS. 15-17 illustrates schematic views of structures employed in the formation of at least a portion of a gate stack for a semiconductor device structure in accordance with one or more embodiments.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, “atomic layer deposition”, abbreviated as “ALD”, can refer to a vapor deposition process in which deposition cycles, such as a plurality of consecutive deposition cycles, are conducted in a reaction space (i.e., one or more reaction chambers). Generally, in ALD processes, during each deposition cycle, a precursor is introduced to a reaction space and is chemisorbed onto a substrate surface, which may include a previously deposited material from a previous deposition cycle or other materials, forming maximally one monolayer of the precursor that does not readily react with additional excess precursor (i.e., a self-limiting reaction). Thereafter, in some cases, another precursor or a reactant may be introduced into the reaction space for use in converting the chemisorbed precursor to the desired material on the substrate surface. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, a “cyclic deposition process” can refer to a method or a process comprising sequentially introducing reactants into a reaction space to deposit a layer or a film on or over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

As used herein, the term “purge” can refer to a procedure in which an inert or substantially inert gas is provided to a reaction chamber in between two pulses of gases (e.g., precursors/reactants) that might otherwise react with each other. For example, a purge, e.g., using an inert gas, such as a noble gas, may be provided between a first precursor pulse and a second precursor pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a first precursor to a reaction chamber, providing a purge gas to the reaction chamber, and providing a second precursor or a reactant to the reaction chamber, wherein the substrate on which a layer is deposited does not move. In the case of spatial purges, a purge step can take the following form: moving a substrate from a first location to which a first precursor is (e.g., continually) supplied, through a purge gas curtain, to a second location to which a reactant or a second precursor is (e.g., continually) supplied.

As used herein, a “layer structure” can refer to a structure including one or more layers overlying the substrate, such as one, two, or a plurality of layers formed according to a method provided herein. A “layer” can refer to a continuous, substantially continuous, or non-continuous material that extends in a direction perpendicular to a thickness direction to cover at least a portion of a surface. A layer may be positioned on a lateral surface and/or on a sidewall of recessed features of a surface. A layer can include two-dimensional materials, three-dimensional materials, nanoparticles, partial or full molecular layers, partial or full atomic layers, and/or clusters of atoms or molecules. A layer may be built up from one or more non-discernable monolayers or sub-monolayers to produce a uniform or a substantially uniform material, wherein the number of monolayers or sub-monolayers influences the thickness of the material. A layer structure may refer to a single layer of material. A layer structure can refer to two or more layers of material, each of the individual layers being disposed on another layer of the layer structure. A layer structure can refer to a plurality of layers of material, each one of the individual layers of the plurality being disposed on another layer of the layer structure. A layer structure can include a “laminate structure”, where a laminate structure can refer to layer structure comprising two or more repeating unit layer structures (e.g., a metal phosphide layer disposed on a metal nitride layer) where a first unit layer structure of the laminate structure is disposed on a second unit layer structure of the laminate structure. A laminate structure can refer to a plurality of discernable individual layers (e.g., as determined by high resolution microscopy techniques). A laminate structure can refer to a plurality of indiscernible individual layers (e.g., as determined by high resolution microscopy techniques). For example, the thickness of the individual layers of the laminate structure and/or the deposition process employed in forming the individual layers may result in a mixing of the individual layers of the laminate structure thereby making the individual layers of the laminate structure indiscernible.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, the term “independently” when used in the context of describing one or more substituent groups (which may be represented as “R”) means that a given R group is independently selected relative to other R groups bearing the same or different subscripts or superscripts and to those lacking a subscript or superscript, but is also independently selected relative to any additional species of that same R group. For example, in the formula CRₙ(NR₂)₄₋ₙ, where n is 0, 1, 2, or 3 and each R is an independently selected substituent, it should be understood that each R group may be distinct, or two or more R groups may be identical to each other. More specifically, where n=3, the formula may be written as C(R¹)(R²)(R³)(NR⁵R⁶), and each of R¹, R², R³, R⁴, R⁵, and R⁶ may be distinct from one another or two or more of R¹, R², R³, R⁴, R⁵, and R⁶ may be identical to each other.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate. As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, a “structure” can be or includes a substrate as described herein. Structures can include one or more layers overlying the substrate, such as one or more layers formed according to a method as described herein. Device portions can be or include structures. Likewise, intermediate device portions can be or include structures.

As used herein, a “substituent” refers to an atom or a group of atoms that replaces one or more atoms (such as a hydrogen atom) or a group of atoms in a parent compound, thereby becoming a new group in the resultant new compound. The substituent is substituted for the original atom or a group of atoms in the parent molecule. For simplicity, a substituent may be indicated in a chemical formula as an “R” group and each “R” group in a compound may be independently selected. Examples of substituent groups include, but are not limited to: a hydrogen atom (H); an “alkyl group”, having a general formula of CₙH₂ₙ₊₁ where n is an integer, such as a saturated linear or branched C₁ to C₁₀ alkyl group, preferably C₁ to C₄ alkyl group (e.g., methyl (Me), ethyl (Et), n-propyl (ⁿPr), iso-propyl (¹Pr), n-butyl (ⁿBu), i-butyl (ⁱBu), sec-butyl (^{s}Bu), and tert-butyl (^{t}Bu)); a “cycloalkyl group”, having a general formula of CₙH₂ₙ₋₁ where n is an integer, such as C₃ to C₆ cyclic alkyl groups (e.g., cyclopropyl, cyclobutyl, cyclopentyl, and cyclohexyl); an “alkenyl group”, such as C₂ to C₆ linear or branched unsaturated hydrocarbons less one hydrogen atom (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl (Cp), and methyl, dimethyl, or ethyl cyclopentadienyl groups; a hydroxy group (OH); an “alkoxy group” having a general formula of CₙH₂ₙ₊₁₀ where n is an integer, such as a linear or branched C₁ to C₁₀ alkoxy group, typically a C₁ to C₄ alkoxy group (e.g., methoxy, ethoxy, n-propoxy, i-propoxy, butoxy, iso-butoxy, sec-butoxy, and tert-butoxy); a “hydroxyalkyl” having a general formula of CₙH₂ₙOH where n is an integer, such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group” having a general formula of CₙH₂ₙSH where n is an integer, such as a linear or branched C₁ to C₆ alkylthiol group (e.g., thiolmethyl, thiolethyl, thiolpropyl, thiolbutyl, thiolpentyl, and thiolhexyl); a silyl group (SiR′₃) where each R′ is independently an H atom, an organic group such as an alkyl group or an aryl group; a amine group (NR′₂) where each R′ is independently an H atom, an organic group such as an alkyl group or an aryl group, or a silyl group; a halide (X), such as fluoride (F), chloride (Cl), bromide (Br), and iodide (I); an “oxyhalide” (OX), such as oxyfluoride (OF), oxychloride (OCl), oxybromide (OBr), and oxyiodide (OI); a “haloalkyl group”, where one or more hydrogen atoms on an alkyl group or a cycloalkyl group is replaced with a halogen, such as a linear or branched C₁ to C₆ haloalkyl group having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl); and a “haloaryl group”, where one or more hydrogen atoms on an aryl is replaced with a halogen, such as, for example a fluorobenzyl group. A substituent group may, in and of itself, be substituted. For example, a hydroxyalkyl group is a substituted alkyl group, where an H atom on the alkyl group is replaced with an OH group.

As used herein, the term “threshold voltage”, abbreviated as “Vt”, refers to a minimum gate voltage required to create a conductive path between the source and drain terminals of a field effect transistor (FET).

As used herein, the term “threshold voltage shifting layer” or “Vt shifting layer” refers to a layer which can be used in the gate stack of a field effect transistor, which can change the threshold voltage of that field effect transistor. When used herein, the term “threshold voltage shifting layer” may be equivalent to like terms such as “threshold voltage adjusting layer”, “work function adjusting layer”, “work function shifting layer”, “flatband voltage adjusting layer”, “flatband voltage shifting layer”, a “dipole layer”, or simply “layer”.

Articles “a” or “an” refer to a species or a genus including multiple species, depending on the context. As such, the terms “a/an”, “one or more”, and “at least one” can be used interchangeably herein.

The term “substantially” as applied to a composition, a method, a system, or a structure generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The terms “on” or “over” may be used to describe a relative location relationship. For example, an element, a film, or a layer may be directly positioned on or over and physically contacting at least a portion another element, film, or layer; or, alternatively, an element, a film, or a layer may be on or over another element, film or layer but have one or more interposed elements, films, or layers therebetween. Therefore, unless the term “directly” is separately used, the terms “on” or “over” will be construed to be a relative concept. Similar to this, it will be understood that the terms “under”, “underlying”, or “below” describe a relative location relationship and should be construed to be relative concepts.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

Unless stated otherwise, reference to a group of elements in the periodic table refers to elements within a given column on the periodic table. The group numbering is based on the International Union of Pure and Applied Chemistry (IUPAC) standards established in 1988 and in effect since. For example, the group 4 elements in the periodic table include titanium (Ti), zirconium (Zr), hafnium (Hf), and rutherfordium (Rf); the group 5 elements in the periodic table include vanadium (V), niobium (Nb), tantalum (Ta), and dubnium (Db); and the group 6 elements in the periodic table include chromium (Cr), molybdenum (Mo), tungsten (W), and seaborgium (Sg). The group 4, 5, and 6 elements are transition state metals. In another example, group 13 elements in the periodic table include boron (B), aluminum (Al), gallium (Ga), indium (In), thallium (Tl), and nihonium (Nh). Notably, boron (B) is a metalloid; however, for the purposes of this disclosure, in some places through the disclosure, boron may be referred to as a metal and it is included with the other group 13 elements as a group 13 metal.

In certain places throughout the disclosure, a chemical compound, a functional group of a chemical compound, or a substituent or ligand may be referred to by a chemical name (e.g., an IUPAC name or a common name), a molecular formula which may be abbreviated, or both. In cases where there is a conflict between the chemical name and the molecular formula, and the identity of the chemical compound, the functional group, or the substituent or ligand cannot be unambiguously ascertained by one of skill in the art, then the molecular formula shall prevail.

Titanium Nitride (TiN) is widely used in various semiconductor device and integrated circuit applications. For example, TiN can be employed as a work function metal (WFM), in DRAM cell electrodes, and as liners and/or barrier layers. TiN is commonly employed due to its superior performance, including stability when in contact with high-k dielectrics, as well as having an acceptable effective work function (eWF) of approximately 4.8 eV. In addition, TiN has as relatively low resistivity of approximately 1000 μΩ·cm at a thickness of approximately 3 nm, while having a high process compatibility. However, there is still a demand for alternative solutions with higher eWF and lower resistivity.

Recently, atomic layer deposition (ALD) of alternative materials to TiN has been investigated, and various alternative materials have demonstrated excellent overall properties, including a high eWF and low resistivity at low layer thicknesses. Nevertheless, some of these alternative materials have drawbacks, such as precursor instability and/or a negative influence on high-k dielectric materials. Therefore, there is a need for alternative material systems and structures that can be deposited in a self-limiting growth manner, offering higher eWF with low resistivity and a low layer thickness.

Accordingly, an aspect of the present disclosure is related to layer structures that comprises one or more metals (M), phosphorus (P), and nitrogen (N). In such embodiments the layer structure can be referred to as a metal, phosphorus, and nitrogen layer structure.

In various embodiments, the metal, phosphorus, and nitrogen layer structures of the disclosure can comprise a layer comprising a metal and phosphorus and may be referred to as a metal and phosphorus containing layer. In some embodiments, the metal and phosphorus containing layer comprises a metal phosphide. In some embodiments, the metal and phosphorus containing layer consists of, or consists essentially of, a metal phosphide. A metal phosphide is a material that comprises M-P bond(s), where some, most, or all of the phosphorus has an oxidation state of −3. A metal phosphide may be represented by the general formula MPₓ, where the “x” is a variable ranging from about 0.1 to about 3, or more typically from about 0.5 to about 2, depending upon the oxidation state of the metal and the process conditions used to form the metal phosphide material. In some embodiments, the metal in the metal phosphide film is one or more of a transition state metal and a group 13 metal (including boron). For example, in some embodiments, the metal is one or more of a rare earth metal, a group 4 metal, a group 5 metal, a group 6 metal, and a group 13 metal. In various embodiments, the metal in the metal phosphide material may have an oxidation state of +2, or +3, or +4, or +5, or +6. Thus, in some embodiments, x is about ⅔, or about 1, or about 4/3, or about 5/3, or about 2. In other embodiments, the value of x may not be rational.

In various embodiments, the metal, phosphorus, and nitrogen layer structures of the disclosure can comprise a layer comprising a metal and nitrogen and may be referred to as a metal and nitrogen containing layer. In some embodiments, the metal and nitrogen containing layer comprises a metal nitride. In some embodiments, the metal and nitrogen containing layer consists of, or consists essentially of, a metal nitride. A metal nitride is a material that comprises M-N bond(s). In some embodiments, the metal in the metal nitride film is one or more of a transition state metal and a group 13 metal (including boron). For example, in some embodiments, the metal is one or more of a rare earth metal, a group 4 metal, a group 5 metal, a group 6 metal, and a group 13 metal.

In various embodiments, the metal, phosphorus, and nitrogen layer structures of the disclosure can comprise a layer comprising a metal, phosphorus, and nitrogen and may be referred to as a metal, phosphorus, and nitrogen containing layer. In some embodiments, the metal, phosphorus, and nitrogen layer can comprise a metal phosphorus nitride layer. In some embodiments, the metal, phosphorus, and nitrogen layer comprises, or consists of, or consist essentially of, a metal phosphorus nitride layer. A metal phosphorus nitride layer is a material that comprises M-N bond(s) and M-P bond(s). In some embodiments, the metal phosphorus nitride layer comprises M-N bond(s) and M-P bond(s) but does not comprise, or does not substantially comprise, P—N bond(s). In some embodiments, the metal phosphorus nitride layer comprises M-N bond(s), M-P bond(s), and P—N bond(s). In some embodiment, the metal phosphorus nitride layer is a mixture of a metal nitride material and a metal phosphide material. It may also be said that a metal phosphorus nitride layer is a metal phosphide material that further comprises nitrogen. A metal phosphorus nitride layer may be represented by the general formula MPₓN_{y}. In some embodiments, the metal in the metal phosphorus nitride layers is one or more of a transition state metal and a group 13 metal (including boron). For example, in some embodiments, the metal is one or more of a rare earth metal, a group 4 metal, a group 5 metal, a group 6 metal, and a group 13 metal.

In various embodiments, the metal, phosphorus, and nitrogen layer structures of the disclosure comprise one or more metal phosphorus nitride layers. In some embodiments, the metal, phosphorus, and nitrogen layer structures of the disclosure comprise one or more metal nitride layers and one or more metal phosphide layers. In some embodiments, the metal, phosphorus, and nitrogen layer structures of the disclosure comprise one or more metal phosphorus nitride layers and one or more metal nitride layers.

In various embodiments the metal, phosphorus, and nitrogen layer structures comprise a laminate structure comprising a repeating unit layer structure. In some embodiments, the unit layer structure comprises a bilayer including a first layer disposed directly on a second layer. In one aspect, the repeating unit layer structure comprises a metal phosphide layer disposed on a metal nitride layer, or a metal nitride layer disposed on a metal phosphide layer. In another aspect, the repeating unit layer structure comprises a metal phosphorus nitride layer disposed on a metal nitride layer, or a metal nitride layer disposed on a metal phosphorus nitride layer.

In some embodiments, the laminate structure comprises a repeating unit layer structure comprising a metal nitride layer including a first metal species (M₁) and a metal phosphide layer including a second metal species (M₂) disposed on the metal nitride layer. In some embodiments, the laminate structure comprises a repeating unit layer structure comprising a metal phosphorus nitride layer including a first metal species (M₁) and a metal nitride layer including a second metal species (M₂) disposed on the metal phosphorus nitride layer. In one aspect, the first metal species (M₁) is the same as the second metal species (M₂). In another aspect, the first metal species (M₁) is different to the second metal species (M₂)

In various embodiments, the metal, phosphorus, and nitrogen layer structures of the disclosure comprise one or more metals (e.g., M₁ and/or M₂).

In some embodiments, the metal, phosphorus, and nitrogen layer structures provided comprises one or more metals selected from a rare earth metal, a group 4 metal, a group 5 metal, a group 6 metal, a group 13 metal, and combinations thereof. In some embodiments, the one or more metals may be selected from scandium (Sc), yttrium (Y), lanthanum (La), cerium (Ce), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations thereof.

In some embodiments, the metal, phosphorus, and nitrogen layer structures provided comprise one or more metals comprising a rare earth metal selected from scandium (Sc), yttrium (Y), or a lanthanide. More specifically, the one or more metals may be selected from scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and combinations and mixtures thereof.

In some embodiments, the one or more metals may be selected from scandium (Sc), yttrium (Y), lanthanum (La), cerium (Ce), and lutetium (Lu).

In some embodiments, the metal, phosphorus, and nitrogen layer structures comprise a rare earth metal phosphide layer. For example, the rare earth metal phosphide layer may comprise, consist essentially of, or consist of one or more of scandium phosphide, yttrium phosphide, lanthanum phosphide, cerium phosphide, praseodymium phosphide, neodymium phosphide, promethium phosphide, samarium phosphide, europium phosphide, gadolinium phosphide, terbium phosphide, dysprosium phosphide, holmium phosphide, erbium phosphide, thulium phosphide, ytterbium phosphide, lutetium phosphide, and combinations and mixtures thereof.

In some embodiments, the metal, phosphorus, and nitrogen layer structures provided comprise a rare earth metal nitride layer. For example, the metal, phosphorus, and nitrogen containing layer may comprise, consist essentially of, or consist of one or more of scandium nitride, yttrium nitride, lanthanum nitride, cerium nitride, praseodymium nitride, neodymium nitride, promethium nitride, samarium nitride, europium nitride, gadolinium nitride, terbium nitride, dysprosium nitride, holmium nitride, erbium nitride, thulium nitride, ytterbium nitride, lutetium nitride, and combinations and mixtures thereof.

In other embodiments, the metal, phosphorus, and nitrogen layer structures provided comprises a rare earth metal phosphorus nitride layer. For example, the metal, phosphorus, and nitrogen layer structures provided may comprise, consist essentially of, or consist of one or more of scandium phosphorus nitride, yttrium phosphorus nitride, lanthanum phosphorus nitride, cerium phosphorus nitride, praseodymium phosphorus nitride, neodymium phosphorus nitride, promethium phosphorus nitride, samarium phosphorus nitride, europium phosphorus nitride, gadolinium phosphorus nitride, terbium phosphorus nitride, dysprosium phosphorus nitride, holmium phosphorus nitride, erbium phosphorus nitride, thulium phosphorus nitride, ytterbium phosphorus nitride, lutetium phosphorus nitride, and combinations and mixtures thereof.

In some embodiments, the metal, phosphorus, and nitrogen layer structures comprises a group 4 element. For instance, the metal may be selected from titanium (Ti), zirconium (Zr), hafnium (Hf), and combinations and mixtures thereof.

In some embodiments, the metal, phosphorus, and nitrogen layer structures provided comprise a layer including a group 4 metal phosphide layer. For example, the group 4 metal phosphide layer can comprise, consist essentially of, or consist of one or more of titanium phosphide, zirconium phosphide, hafnium phosphide, and combinations and mixtures thereof.

In some embodiments, the metal, phosphorus, and nitrogen layer structures provided comprise a layer including a group 4 metal nitride layer. For example, the group 4 metal nitride layer can comprise, consist essentially of, or consist of one or more of titanium nitride, zirconium nitride, hafnium nitride, and combinations and mixtures thereof.

In other embodiments, the metal, phosphorus, and nitrogen layer structures provided comprise a group 4 metal phosphorus nitride layer. For example, the group 4 metal phosphorus nitride layer may comprise, consist essentially of, or consist of one or more of titanium phosphorus nitride, zirconium phosphorus nitride, hafnium phosphorus nitride, and combinations and mixtures thereof.

In some embodiments, the metal, phosphorus, and nitrogen layer structures provided includes a group 5 element. For instance, the metal may be selected from vanadium (V), niobium (Nb), tantalum (Ta), and combinations and mixtures thereof.

In some embodiments, the metal, phosphorus, and nitrogen layer structures provided comprise a group 5 metal phosphide layer. For example, the group 5 metal phosphide layer may comprise, consist essentially of, or consist of one or more of vanadium phosphide, niobium phosphide, tantalum phosphide, and combinations and mixtures thereof.

In some embodiments, the metal, phosphorus, and nitrogen layer structures provided comprise a group 5 metal nitride layer. For example, the group 5 metal nitride layer may comprise, consist essentially of, or consist of one or more of vanadium nitride, niobium nitride, tantalum nitride, and combinations and mixtures thereof.

In other embodiments, the metal, phosphorus, and nitrogen layer structures provided comprise a group 5 metal phosphorus nitride layer. For example, the group 5 metal phosphorus nitride layer may comprise, consist essentially of, or consist of one or more of vanadium phosphorus nitride, niobium phosphorus nitride, tantalum phosphorus nitride, and combinations and mixtures thereof.

In some embodiments, the metal, phosphorus, and nitrogen layer structures provided comprise a group 6 element. For instance, the metal may be selected from chromium (Cr), molybdenum (Mo), tungsten (W), and combinations and mixtures thereof.

In some embodiments, the metal, phosphorus, and nitrogen layer structures provided comprise a group 6 metal phosphide layer. For example, the group 6 metal phosphide layer may comprise, consist essentially of, or consist of one or more of chromium phosphide, molybdenum phosphide, tungsten phosphide, and combinations and mixtures thereof.

In some embodiments, the metal, phosphorus, and nitrogen layer structures provided comprise a group 6 metal nitride layer. For example, the group 6 metal nitride layer may comprise, consist essentially of, or consist of one or more of chromium nitride, molybdenum nitride, tungsten nitride, and combinations and mixtures thereof.

In other embodiments, the metal, phosphorus, and nitrogen layer structures provided comprise a group 6 metal phosphorus nitride layer. For example, the group 6 metal phosphorus nitride layer may comprise, consist essentially of, or consist of one or more of chromium phosphorus nitride, molybdenum phosphorus nitride, tungsten phosphorus nitride, and combinations and mixtures thereof.

In some embodiments, the metal, phosphorus, and nitrogen layer structures provided comprise a group 9 element. For instance, the metal may be selected from cobalt (Co), rhodium (Ru), iridium (Ir), and combinations and mixtures thereof.

In some embodiments, the metal, phosphorus, and nitrogen layer structures provided comprise a group 9 metal phosphide layer. For example, the group 9 metal phosphide layer may comprise, consist essentially of, or consist of one or more of cobalt phosphide, rhodium phosphide, iridium phosphide, and combinations and mixtures thereof.

In some embodiments, the metal, phosphorus, and nitrogen layer structures provided comprise a group 9 metal nitride layer. For example, the group 9 metal nitride layer may comprise, consist essentially of, or consist of one or more of cobalt nitride, rhodium nitride, iridium nitride, and combinations and mixtures thereof.

In other embodiments, the metal, phosphorus, and nitrogen layer structures provided comprise a group 9 metal phosphorus nitride layer. For example, the group 9 metal phosphorus nitride layer may comprise, consist essentially of, or consist of one or more of cobalt phosphorus nitride, rhodium phosphorus nitride, iridium phosphorus nitride, and combinations and mixtures thereof.

In some embodiments, the metal, phosphorus, and nitrogen layer structures provided comprise a group 13 element. For instance, the metal may be selected from boron (B), aluminum (Al), gallium (Ga), indium (In), and combinations and mixtures thereof.

In some embodiments, the metal, phosphorus, and nitrogen layer structures provided comprises a group 13 metal phosphide layer. For example, the group 13 metal phosphide layer may comprise, consist essentially of, or consist of one or more of boron phosphide, aluminum phosphide, gallium phosphide, indium phosphide, and combinations and mixtures thereof.

In some embodiments, the metal, phosphorus, and nitrogen layer structures provided comprise a group 13 metal nitride layer. For example, the group 13 metal nitride layer may comprise, consist essentially of, or consist of one or more of boron nitride, aluminum nitride, gallium nitride, indium nitride, and combinations and mixtures thereof.

In other embodiments, the metal, phosphorus, and nitrogen layer structures provided comprise a group 13 metal phosphorus nitride layer. For example, the group 13 metal phosphorus nitride layer may comprise, consist essentially of, or consist of one or more of boron phosphorus nitride, aluminum phosphorus nitride, gallium phosphorus nitride, indium phosphorus nitride, and combinations and mixtures thereof.

The metal, phosphorus, and nitrogen layer structures of the disclosure may be position on or over at least a portion of a surface of a substrate, either directly on the substrate or on one or more other layers on the substrate, or it may be interposed between two or more other layers that are on the substrate. The substrate is not particularly limited and may be a semiconductor wafer or multiple semiconductor wafers. The substrate may comprise one or more material layers such as dielectric layers, insulating layers, metal layers, sacrificial layers, and so forth, in addition to the metal and phosphorus containing layer. The substrate may include various topological features, such as gaps, recesses, lines, trenches, vias, holes, or spaces between elevated portions formed within or on at least a portion of a layer of the substrate. The metal, phosphorus, and nitrogen layer structures may cover the entire surface of the substrate or only a portion of the substrate and may be present on the lateral surface(s) and/or the vertical surface(s) or sidewall(s) of various topological features if present. In some embodiments, the substrate is a silicon wafer. The silicon wafer may be a monocrystalline silicon wafer (e.g., a p-type monocrystalline silicon wafer). Alternatively, the silicon wafer may comprise silicon-germanium (SiGe). In some embodiments, the substrate further comprises a dielectric layer. The dielectric layer may essentially be one material layer, or it can comprise multiple thinner material layers of two or more materials. The dielectric layer may comprise silicon oxide. Additionally, or alternatively, the dielectric layer may comprise a high-K material. In some embodiments, the substrate further comprises one or more of a metal layer and a capping layer. The different material layers may form a structure on the surface of the substrate. The structure can be or form part of a CMOS structure, such as one or more of a PMOS and NMOS structure, or other device structures.

In some embodiments, the metal, phosphorus, and nitrogen layer structures comprise a threshold voltage shifting layer in a semiconductor device structure. For example, the metal, phosphorus, and nitrogen layer structures may be a threshold voltage shifting layer in a gate stack of a FET, such as a MOSFET. In these embodiments, the metal, phosphorus, and nitrogen layer structures may be disposed on or over a substrate comprising a dielectric layer, such as, for example a SiO₂ layer and/or a high-k material layer. In these embodiments, the metal, phosphorus, and nitrogen layer structures may additionally or alternatively be disposed on or over a substrate comprising an interlayer or an interface layer. In these embodiments, the thickness of the metal, phosphorus, and nitrogen layer structure is typically less than 2 nm, or more typically less than 1 nm, or even less than 0.1 nm. Further, the metal, phosphorus, and nitrogen layer structure may have a low oxygen content or be oxygen free. Additionally, or alternatively, the metal, phosphorus, and nitrogen layer structure may have a low carbon content or be carbon free.

### Precursors

Various embodiments include methods and processes for forming metal, phosphorus, and nitrogen layer structures. Such methods and processes employ suitable precursors for the formation and/or deposition of the metal, phosphorus, and nitrogen containing layers. In some embodiments the metal, phosphorus, and nitrogen layer structures of the disclosure are deposited employing one or more phosphorus precursors, one or more nitrogen precursors, and one or more metal precursors, as described in detail below.

### Phosphorus Precursors

In some embodiments, the phosphorus precursor is selected from the group consisting of: tetraphosphorus (P₄); phosphorus pentoxide (P₂O₅); phosphine (PH₃); an organophosphine (PH₃₋ₙRₙ where each R is a substituent independently selected from an alkyl group, a alkyl halide, an aryl group, and an aryl halide and n is 1, 2, or 3), such as, for example an alkyl phosphine or an aryl phosphine, more specifically, for example PR₃, PHR₂, and PH₂R, where R each is independently selected from a Me, Et, ⁿPr, ⁱPr, ⁿBu, ⁱBu, ^{s}Bu, ^{t}Bu, and Ph; an aminophosphine (PR₃₋ₙ(NR₃)ₙ where each R is a substituent independently selected from a hydrogen atom, an alkyl group, and an aryl group and n is 1, 2, or 3), such as, for example PH₂(NR₂), PH(NR₂)₂, and P(NR₂)₃, where R each is independently selected from a Me, Et, ⁿPr, ⁱPr, ⁿBu, ⁱBu, ^{s}Bu, ^{t}Bu, and Ph; a phosphoramide (P(O)(NR₂)ₙ(OR)₃₋ₙ where each R is a substituent independently selected from a hydrogen atom, an alkyl group, and an aryl group and n is 1, 2, or 3) such as, for example P(O)(NR₂)₃, P(O)(NR₂)₂(OR), and P(O)(NR₂)(OR)₂ where R each is independently selected from H, Me, Et, ⁿPr, ⁱPr, ⁿBu, ⁱBu, ^{s}Bu, ^{t}Bu, and Ph; a silylphosphide (PR₃₋ₙ(SiR₃)ₙ where each R is a substituent independently selected from a hydrogen atom, an alkyl group, an alkyl halide group, an aryl group, and an aryl halide group and n is 1, 2, or 3), such as, for example P(SiR₃)₃, PR(SiR₃)₂, PR₂(SiR₃) where R each is independently selected from H, Me, Et, ⁿPr, ⁱPr, ⁿBu, ⁱBu, ^{s}Bu, ⁱBu, and Ph; a silylphosphite (P(OSiR₃)ₙ(OR)₃₋ₙ where each R is a substituent independently selected from a hydrogen atom, an alkyl group, alkyl halide group, an aryl group, and an aryl halide group and n is 1, 2, or 3) such as, for example P(OSiR₃)₃ where R each is independently selected from H, Me, Et, ⁿPr, ⁱPr, ⁿBu, ⁱBu, ^{s}Bu, ^{t}Bu, and Ph.; a silylphosphate (P(O)(OSiR₃)ₙ(OR)₃₋ₙ where each R is a substituent independently selected from a hydrogen atom, an alkyl group, alkyl halide group, an aryl group, and an aryl halide group and n is 1, 2, or 3) such as, for example P(O)(OSiR₃)₃ where R each is independently selected from H, Me, Et, ⁿPr, ⁱPr, ⁿBu, ⁱBu, ^{s}Bu, ^{t}Bu, and Ph.; a phosphite ester (PHₙ₋₃(OR)ₙ or PRₙ₋₃(OR)ₙ where each R is a substituent independently selected from an alkyl group, an alkyl halide group, an aryl group, and an aryl halide group and n is 1, 2, or 3) such as, for example P(OR)₃ where R each is independently selected from Me, Et, ⁿPr, ⁱPr, ⁿBu, ⁱBu, ^{s}Bu, ^{t}Bu, and Ph.; a phosphate ester (P(O)H₃₋ₙ(OR)ₙ or P(O)R₃₋ₙ(OR)ₙ where each R is a substituent independently selected from an alkyl group, an alkyl halide group, an aryl group, and an aryl halide group and n is 1, 2, or 3), such as, for example P(O)(OR)₃ where R each is independently selected from Me, Et, ⁿPr, ⁱPr, ⁿBu, ⁱBu, ^{s}Bu, ^{t}Bu, and Ph.; a phosphorous halide (PX₃ or PX₅, where each X is independently selected from Cl, Br, and I); and a phosphoryl halide (POX₃ where each X is independently selected from Cl, Br, and I).

In various embodiments, suitable phosphorous precursors include, but are not limited to, phosphine (PH₃), tetraphosphorus (P₄), 1,2-diphosphinoethane (C₂H₈P₂), methyl phosphine (PH₂Me), trimethyl phosphine (PMe₃), ethyl phosphine (PH₂Et),triethyl phosphine (PEt₃), isopropylphosphine (PH₂ⁱPr), i-butylphosphine (PH₂ⁱBu), t-butylphosphine (PH₂^{t}Bu), dichloromethylphosphine (MePCl₂), dichloroethylphosphine (PCl₂Et), dichloropropylphosphine (PCl₂ⁿPr), dichloroisopropylphosphine (PCl₂ⁱPr), dichlorobutylphosphine (PCl₂ⁿBu), dichlorotertbutylphosphine (PCl₂^{t}Bu), (PClⁱPr₂), chloro(dimethyl)phosphine (PClMe₂), chloro(diethyl)phosphine (PClEt₂), chloro(di-secbutyl)phosphine (PCl^{s}Bu₂), bromo(di-secbutyl)phosphine (PBr^{t}Bu₂), chloro(di-tertbutyl)phosphine (PCl^{t}Bu₂), chloro(tertbutyl)(methyl)phosphine (PCl^{t}BuMe), cyclohexylphosphine (PH₂(C₆H₁₁), phenyl phosphine (PH₂Ph), 1,2-diphosphinobenzene, tris(N-pyrrolidinyl)phosphine, dimethylaminophosphine (PH₂(NMe₂)₂), bis(dimethylamino)phosphine (PH(NMe₂), dimethylamino(methyl)phosphine(PMe(NMe₂)₂), tris(dimethylamino)phosphine (P(NMe₂)₃), tris(diethylamino)phosphine (P(NEt₂)₃), chlorobis(dimethylamino)phosphine (PCl(NMe₂)₂), dichloro(dimethylamino)phosphine (PCl₂(NMe₂)), dichloro(diethylamino)phosphine (PCl₂(NEt₂)), chlorobis(diethylamino)phosphine (PCl(NEt₂)₂), chlorobis(diisopropylamino)phosphine (PCl(NⁱPr₂)₂), dichloro(diisopropylamino)phosphine (PCl₂(NiPr₂)), tris(dimethylamino)phosphine (P(═NH)(NMe₂)₃), trisilylphosphine (P(SiH₃)₃), tris(trimethylsilyl) phosphine (P(SiMe₃)₃), tris(triethylsilyl) phosphine (P(SiEt₃)₃), tris(trimethylsiloxy)phosphine (P(OSiMe₃)₃), trimethyl phosphite (POMe₃), trimethyl phosphate (P(O)OMe₃), phosphorus pentoxide (P₂O₅), phosphorous trichloride (PCl₃), phosphorous tribromide (PBr₃), phosphorous triiodide (PI₃), phosphorous pentachloride (PCl₅), phosphorous pentabromide (PBr₅), phosphoryl chloride (POCl₃), and phosphoryl bromide (POBr₃).

In some embodiments, the phosphorus precursor is not phosphine (PH₃).

In some embodiments, the phosphorus precursor comprises an alkylphosphine, having the formula RₓPH₃₋ₓ, where x ranges from zero to 3 and R is an alkyl selected from the group consisting of ethyl, methyl, butyl or propyl, may be used as the Group-VA element-containing compound. In some embodiments, alkylphosphines may be selected from the group consisting of diethylphosphine, triethylphosphine, dimethylphosphine, trimethylphosphine and mixtures thereof.

### Metal Precursors

A number of suitable metal precursors may be utilized in the methods disclosed herein. In some embodiments, the metal in metal precursor is a transition state metal or a group 13 element. For example, in some embodiments, the metal is one or more of a rare earth element, a group 4 element, a group 5 element, a group 6 element, and a group 13 element. In some embodiments, the metal in the metal precursor is selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations and mixtures thereof. In some embodiments, the metal in the metal precursor is selected from the group consisting of scandium (Sc), yttrium (Y), lanthanum (La), cerium (Ce), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations and mixtures thereof.

In some embodiments, the metal precursor comprises a metal and one or more ligands coordinated around the metal (ML). The number of ligands in the metal precursor depends upon the oxidation state of the metal, which may vary in different embodiments of the disclosure and may be +2, or +3, or +4, or +5, or +6. Suitable ligands include, but are not limited to, a halide, a carbonyl, an oxo, an alkyl, a cyclopentadienyl, an η⁶-arene, an alkoxide, an imido, an alkyl amide, a silyl amide, a 3-diketonate, an amidinate, a diazadiene, and a triazenide. In some embodiments, the metal precursor comprises one type of ligand (i.e., it is homoleptic), while in other embodiments, the metal precursor comprises two types of ligands, or three types of ligands, or more (i.e., it is heterolytic). In some embodiments, the metal precursor comprises one or more halide ligands (generically represented by “X”), such as fluoride (F), chloride (Cl), bromide (Br), or iodide (I) ligands. Coordination of halide ligand to the metal occurs through a M-X bond. In some embodiments, the metal precursor comprises one or more carbonyl ligands (CO). Coordination of a carbonyl ligand to the metal occurs through a M-C bond. In some embodiments, the metal precursor comprises one or more oxo ligands (02-). Coordination of an oxo ligand can occur to one metal center as an M-O bond (generally a double or triple bond) or to two metal centers as M-O-M bonds. In some embodiments, the metal precursor comprises one or more alkyl ligands. An alkyl ligand may have a linear or branched structure with a general formula of CₙHₙ₊₁ where n is an integer that is typically between 1 and 10, more typically between 1 and 5. Coordination of an alkyl ligand to a metal occurs through a M-C bond. Example alkyl ligands include, but are not limited to, methyl (Me), ethyl (Et), n-propyl (ⁿPr), iso-propyl (ⁱPr), n-butyl (ⁿBu), sec-butyl (^{s}Bu), tert-butyl (^{t}Bu), neopentyl (ⁿPe), and tert-pentyl (^{t}Pe). In some embodiments, the metal precursor comprises one or more cyclopentadienyl ligands. A cyclopentadienyl ligand has a general formula of C₅R₅ where each R is an independently selected substituent, typically selected from a hydrogen, an alkyl, an alkyl halide, or a halogen. Coordination of a cyclopentadienyl ligand to the metal generally occurs through a pentahapto (η⁵) bonding mode. Example cyclopentadienyl ligands include, but are not limited to, cyclopentadienyl (Cp), methylcyclopentadienyl (MeCp), dimethylcyclopentadienyl (Me₂Cp), ethylcyclopentadienyl (EtCp), isopropylcyclopentadienyl (ⁱPrCp), isopropylcyclopentadienyl (ⁱPrCp), tert-butylcyclopentadienyl (^{t}BuCp), trimethylsilylcyclopentadienyl (TMSCp), pentamethylcyclopentadientyl (Cp*), 1,2,4-triisopropylcyclopentadienyl (ⁱPr₃Cp), and 1,2,4-tri-tert-butylcyclopentadienyl (^{t}Bu₃Cp). In some embodiments, the metal precursor comprises one or more η⁶-arene ligands. The simplest η⁶-arene ligands are benzene (C₆H₆) and substituted benzenes have a general formula of C₆R₆ where each R is an independently selected substituent, typically selected from a hydrogen, an alkyl group, an alkyl halide group, and a halogen. Coordination of an η⁶-arene ligand to the metal generally occurs through a hexahapto (η⁶) bonding mode. Example benzene ligands include, but are not limited to, benzene (Ben), methyl benzene (MeBen), and ethyl benzene (EtBen). In some embodiments, the metal precursor comprises one or more alkoxide ligands. An alkoxide ligand has a general formula of RO⁻ where R is a substituent, typically selected from an alkyl group, an alkyl halide an aryl group, an aryl halide, an alkenyl group, an alkynyl group, and an alkylsilyl group. Coordination of an alkoxide ligand to a metal occurs through a M-O bond. Example alkoxide ligands include, but are not limited to, methoxide (MeO), ethoxide (EtO), n-propoxide (ⁿPrO), isopropoxide (ⁱPrO), n-butoxide (ⁿBuO), sec-butoxide (^{s}BuO), tert-butoxide (^{t}BuO), 1-methoxy-2-methyl-2-propoxide (mmp), 1-dimethylamino-2-propoxide (dmap), 1-dimethylamino-2-methyl-2-propoxide (dmamp), and 1-dimethylamino-2-methyl-2-butoxide (dmamb), and phenoxide (PhO). In some embodiments, the metal precursor comprises one or more imido ligands. An imide ligand has a general formula of N—R, where R is a substituent, typically selected from an alkyl group, an alkyl halide group, an aryl group, an aryl halide group, an alkenyl group, an alkynyl group, and an alkylsilyl group. Coordination of an imido ligand to a metal occurs through a M=N bond. Example imide ligands include, but are not limited to, imido (NH), methylimido (NMe), ethylimido (NEt), isopropylimido (NⁱPr), tertbutylimido (N^{t}Bu), and phenylimido (NPh). In some embodiments, the metal precursor comprises one or more organoamindo ligands. An organoamido ligand has a general formula of NHR or NR₂ where each R is an independently selected substituent, typically selected from an alkyl group, an alkyl halide group, an aryl group, an aryl halide group, an alkenyl group, and an alkynyl group. Coordination of an organoamide ligand to a metal occurs through a M-N bond. Example organoamide ligands include, but are not limited to, methyl amido (NHMe), dimethyl amido (NMe₂), ethyl amido (NHEt), diethyl amido (NEt₂), ethyl methyl amido (NMeEt), iso-propyl amido (NHⁱPr), diisopropyl amido (NⁱPr₂), tert-butyl amido (NH^{t}Bu), and phenyl amido (NHPh). In some embodiments, the metal precursor comprises one or more silylamide ligands. A silylamide ligand has a general formula of NH(SiR₃) or N(SiR₃)₂ where each R is an independently selected substituent, typically selected from an alkyl group, an alkyl halide group, an aryl group, an aryl halide group, an alkenyl group, and an alkynyl group. Coordination of a silylamido ligand to a metal occurs through a M-N bond. Example silylamide ligands include but are not limited to bis(trimethylsilyl)amido (N(SiMe₃)₂, abbreviated as “hmds”). In some embodiments, the metal precursor comprises one or more 3-diketonate ligands. A 3-diketonate ligand has a general structure of RC(O)C(R)C(O)R where each R is an independently selected substituent, typically selected from a hydrogen, an alkyl group, an alkyl halide group, an aryl group, an aryl halide group, an alkenyl group, an alkynyl group, an alkylsilyl group, and a halogen. Additionally, or alternatively, two or more R groups may be connected to form one or more condensed ring structures. Coordination of a 3-diketonate ligand to the metal typically occurs through two M-O bonds to form a six-membered chelate ring. Example 3-diketonate ligands include, but are not limited to, acetylacetonate (CH₃C(O)CHC(O)CH₃, abbreviated as “acac”), hexafluoroacetylacetonate (CF₃C(O)CHC(O)CF₃, abbreviated as “hfac”), and 2,2,6,6-tetramethyl-3,5-heptanedionate ((CH₃)₃CC(O)CHC(O)C(CH₃)₃, abbreviated as “thd”). In some embodiments, the metal precursor comprises one or more amidinate ligands (abbreviated as AMD). An amidinate ligand has a general structure NRC(R)NR⁻ where each R is an independently selected substituent, typically selected from a hydrogen, an alkyl group, an alkyl halide group, an aryl group, an aryl halide group, an alkenyl group, an alkynyl group, an alkylsilyl group, and a halogen. Additionally, or alternatively, two or more R groups may be connected to form one or more condensed ring structures. Coordination of an amidinate ligand to a metal typically occurs through two M-N bonds to form a four-membered chelate ring. Example amidinate ligands include, but are not limited to N,N′-diisopropylformamidinate (CH₃CH(CH₃)NC(H)NCH(CH₃)CH₃, abbreviated as “ⁱPrFMD”), N,N′-di-tert-butylformamidinate (CH₃C(CH₃)₂NC(H)NC(CH₃)₂CH₃, abbreviated as “^{t}BuFMD”), N,N′-di-iso-propylacetamidinate (CH₃CH(CH₃)NC(CH₃)NCH(CH₃)CH₃, abbreviated as “ⁱPrAMD”), N,N′-di-tert-butylacetamidinate (CH₃C(CH₃)₂NC(CH₃)NC(CH₃)₂CH₃, abbreviated as “^{t}BuAMD”), and N,N′-di-sec-butylacetamidinate (CH₃CH₂CH(CH₃)NC(CH₃)NCH(CH₃)CH₂CH₃, abbreviated as “^{s}BuAMD”). In some embodiments, the metal precursor comprises one or more 1,4-diazadiene ligands (abbreviated as “DAD”). A 1,4-diazadiene ligand has a general structure of NRC(R)C(R)NR and may be in a neutral, anionic, or dianionic form, where each R is an independently selected substituent, typically selected from a hydrogen, an alkyl group, an alkyl halide group, an aryl group, an aryl halide group, an alkenyl group, an alkynyl group, a trialkylsilyl group, and a halogen. Additionally, or alternatively, two or more R groups may be connected to form one or more condensed ring structures, such as that of a bipyridine ligand (abbreviated as “bpy”) or terpyridine ligand (abbreviated as “tpy”). Coordination of a DAD ligand to the metal typically occurs through two M-N bonds to form a five-membered chelate ring. Example DAD ligands include, but are not limited to, 1,4-di-tert-butyl-1,4-diaza-1,3-butadiene (tBu₂DAD), 1,4-diisopropyl-1,4-diaza-1,3-butadiene (ⁱPr₂DAD), 1,4-di-sec-butyl-1,4-diaza-1,3-butadiene (^{s}Bu₂DAD) and 1,4-di-tert-pentyl-1,4-diaza-1,3-butadiene (^{t}Pn₂DAD). In some embodiments, the metal precursor comprises one or more 3-diketimine ligands (abbreviated as “NacNac”). A 3-diketimine ligand has a general structure NRC(R)C(R)C(R)NR where each R is an independently selected substituent, typically selected from a hydrogen, an alkyl group, an alkyl halide group, an aryl group, an aryl halide group, an alkenyl group, an alkynyl group, a trialkylsilyl group, and a halogen. Additionally, or alternatively, two or more R groups may be connected to form one or more condensed ring structures. Coordination of a 3-diketimine ligand to a metal typically occurs through two M-N bonds to form a six-membered chelate ring. In some embodiments, the metal precursor comprises one or more triazenide ligands. A triazenide ligand has a general structure RNNNR where each R is an independently selected substituent, typically selected from a hydrogen, an alkyl group, an alkyl halide group, an aryl group, an aryl halide group, an alkenyl group, an alkynyl group, a trialkylsilyl group, and a halogen. Coordination of a triazenide ligand to a metal typically occurs through two M-N bonds to form a four-membered chelate ring. An example triazenide ligand is 1,3-bisphenyltriazenide (PhNNNPh).

In some embodiments, the metal precursor comprises a group 4 element. For instance, the metal in the metal precursor may be selected from titanium (Ti), zirconium (Zr), hafnium (Hf), and combinations and mixtures thereof. Examples of metal precursors that comprise titanium, include, but are not limited to, titanium tetrafluoride (TiF₄), titanium tetrachloride (TiCl₄), titanium tetrabromide (TiBr₄), titanium tetraiodide (TiI₄), titanium tetramethoxide (Ti(OMe)₄), titanium tetraethoxide (Ti(OEt)₄), titanium tetraisopropoxide (Ti(OⁱPr)₄), tetrakis(dimethylamido)titanium (Ti(NMe₂)₄), tetrakis(diethylamido)titanium (Ti(NEt₂)₄), and tris(dimethylamido)methylcyclopentadienyl titanium (Ti(MeCp)(NMe₂)₃). Examples of metal precursors that comprise zirconium, include, but are not limited to, zirconium tetrachloride (ZrCl₄·), zirconium tetrabromide (ZrBr₄), zirconium tetramethoxide (Zr(OMe)₄), zirconium tetraethoxide (Zr(OEt)₄), zirconium tetratertbutyl (Zr(O^{t}Bu)₄), tetrakis(dimethylamido)zirconium (Zr(NMe₂)₄), tetrakis(ethylmethylamido)zirconium (Zr(N(Me)(Et))₄), dicyclopentadienyl zirconium dichloride (ZrCl₂Cp₂), (dicyclopentadienyl)(dimethyl)zirconium (ZrMe₂Cp₂), cyclopentadienyltris(dimethylamino)zirconium (ZrCp(NMe₂)₃), and tris(N,N′-diisopropylacetamidinato) zirconium (Zr(ⁱPr₂AMD)₃). Examples of metal precursors that comprise hafnium, include, but are not limited to, hafnium tetrachloride (HfCl₄), hafnium tetrabromide (HfBr₄), tetrakis(1-methoxy-2-methyl-2-propoxy)hafnium (Hf(OC(CH₃)₂CH₂OCH₃)₄), tetra(tert-butoxy)hafnium (Hf(O^{t}Bu)₄), tetrakis(dimethylamido)hafnium (Hf(NMe₂)₄), tetrakis(diethylamido)hafnium (Hf(NEt₂)₄), tetrakis(ethylmethylamido)hafnium (Hf(N(Me)(Et))₄), tetra(1-methoxy-2-methyl-2-propoxy)hafnium (Hf(mmp)₄), and tris(dimethylamido)cyclopentadienylhafnium (HfCp(NMe₂)₃). Other metal precursors comprising titanium, zirconium, and/or hafnium are known in the art. One of skill in the art will recognize other group 4 metal ligand combinations that are suitable for the methods disclosed herein.

In some embodiments, the metal precursor comprises a group 5 element. For instance, the metal in the metal precursor may be selected from vanadium (V), niobium (Nb), tantalum (Ta), and combinations and mixtures thereof. Examples of metal precursors that comprise vanadium, include, but are not limited to, vanadium pentafluoride (VF₅), vanadium pentabromide (VBr₅), vanadium tetrachloride (VCl₄), vanadium oxide trichloride (VOCl₃), tris(isopropoxy)oxovanadium (VO(OⁱPr)₃, tetrakis(ethylmethylamido)vanadium (V(NEtMe)₄), tris(N,N′-diethylacetamidinato) vanadium (V(Et₂AMD)₃), tris(N,N′-diisopropylacetamidinato) vanadium (V(ⁱPr₂AMD)₃), and vanadium acetylacetonate (V(acac)₃). Examples of metal precursors that comprise niobium, include, but are not limited to, niobium pentafluoride (NbF₅), niobium pentachloride (NbCl₅), niobium pentaiodide (NbI₅), niobium pentabromide (NbBr₅), niobium pentaethoxide (Nb(OEt)₅), tetrakis(2,2,6,6,-tetramethylheptane-3,5-dionato) niobium (Nb(thd)₄), pentakis(dimethylamido) niobium (Nb(NMe₂)₅), pentakis(diethylamido) niobium (Nb(NEt₂)₅), tris(diethylamido)(tert-butylimido)niobium (Nb(N^{t}Bu)(NEt₂)₃), tris(dimethylamido)(tert-butylimido)niobium (Nb(N^{t}Bu)(NMe₂)₃), tris(ethylmethylamido)(tert-butylimido)niobium (Nb(N^{t}Bu)(NEtMe)₃), and (tert-amylimido)tris(tert-butoxy)niobium (Nb(N^{t}Amyl)(O^{t}Bu)₃). Examples of metal precursors that comprise tantalum, include, but are not limited to, tantalum pentachloride (TaCl₅), tantalum pentabromide (TaBr₅), tantalum pentaiodide (TaI₅), pentakis(dimethylamido)tantalum (Ta(NMe₂)₅), tantalum pentaethoxide (Ta(OEt)₅), pentakis(diethylamido)tantalum (Ta(NEt₂)₅), tris(diethylamido)(tert-butylimido)tantalum (Ta(N^{t}Bu)(NEt₂)₃), tris(dimethylamido)(tert-butylimido) tantalum (Ta(N^{t}Bu)(NMe₂)₃), tris(ethylmethylamido)(tert-butylimido)tantalum (Ta(N^{t}Bu)(NE^{t}Me)₃), tris(dimethylamido)(tert-amylimido) tantalum (Ta(N^{t}Amyl)(NMe₂)₃), bis(diethylamido)cyclopentadienyl(tert-butylimido)tantalum (TaCp(N^{t}Bu)(NEt₂)₂) (dimethylamido) bis(N,N′-isopropylacetamidinato)(tert-butylimido)tantalum (Ta(N^{t}Bu)(ⁱPrAMD)₂(NMe₂)), (tert-butylimido)tris(3,5-di-tert-butylpyrazolate)tantalum, (Ta(N^{t}Bu)(^{t}Bu₂pz)₃), (isopropylimido)tris(tert-butoxy)tantalum (Ta(NⁱPr)(O^{t}Bu)₃), and (tert-butylimido)tris(tert-butoxy)tantalum (Ta(N^{t}Bu)(O^{t}Bu)₃). Other metal precursors comprising vanadium, niobium, or tantalum are known in the art. One of skill in the art will recognize other group 5 metal ligand combinations that are suitable for the methods disclosed herein.

In some embodiments, the metal precursor comprises a group 6 element. For instance, the metal in the metal precursor may be selected from chromium (Cr), molybdenum (Mo), tungsten (W), and combinations and mixtures thereof. Examples of metal precursors that comprise chromium, include, but are not limited to, tris(2,2,6,6-tetramethyl-3,5-heptanedionato)chromium (Cr(thd)₃), chromyl chloride (CrO₂Cl₂), bis(cyclopentadienyl)chromium (CrCp₂), bis(ethylbenzene)chromium (CrEtBz), chromium acetylacetonate (Cr(acac)₃), and chromium hexacarbonyl (Cr(CO)₆). Examples of metal precursors that comprise molybdenum, include, but are not limited to, molypentachloride (MoCl₅), dichlorodioxomolybdenum (MoO₂Cl₂), tetrakis(dimethylamide) molybdenum (Mo(NMe₂)₄), tetrakis(diethylamide)molybdenum (Mo(NEt₂)₄), bis(tert-butylimido)bis(tert-butoxy)molybdenum (Mo(tBuN)₂(NMe₂)₂), bis(tert-butylimido)bis(ethoxy)molybdenum (Mo(^{t}BuN)₂(NEt₂)₂), 2,2,6,6-tetramethylheptane-3,5-dionatomolybdenum (Mo(thd)₃), molybdenum acetylacetonate Mo(acac)₃, molybdenum hexacarbonyl (Mo(CO)₆), biscyclopentadienyldihydridomolybdenum Mo(Cp)₂H₂, bis(isopropyl)cyclopentadienyldihydridomolybdenum (Mo(ⁱPrCp)₂H₂), bis(N,N′-isopropylacetamidinato)(tert-butylimido)molybdenum (Mo(N^{t}Bu)₂(ⁱPrAMD)₂), and bis(ethylbenzene) molybdenum (Mo(η⁶-EtBz)₂. Examples of metal precursors that comprise tungsten, include, but are not limited to, tungsten pentachloride (WCl₅), tungsten hexafluoride (WF₆), tungsten hexacarbonyl (W(CO)₆), bis(tert-butylimido)bis(dimethylamido)tungsten (W(N^{t}Bu)₂(NMe₂)), bis(N,N′-isopropylacetamidinato)(tert-butylimido)tungsten (W(N^{t}Bu)₂(ⁱPrAMD)₂), and bis(isopropyl)cyclopentadienyldihydridotungsten (W(ⁱPrCp)₂H₂). Other metal precursors comprising chromium, molybdenum, or tungsten are known in the art. One of skill in the art will recognize other group 6 metal ligand combinations that are suitable for the methods disclosed herein.

In other embodiments, the metal precursor comprises a group 13 element. For instance, the metal in the metal precursor may be selected from boron (B), aluminum (Al), gallium (Ga), indium (In), and combinations and mixtures thereof. Examples of metal precursors that comprise boron, include, but are not limited to, trimethylborate (B(OMe)₃), trimethylborane (BMe₃), triethylborane (BEt₃), tris(dimethylamino)borane (B(NMe₂)₃), boron tribromide (BBr₃), boron trichloride (BCl₃), boron triiodide (BI₃), borazine (B₃H₄N₃) and trichloroborazine (B₃Cl₃H₃N₃). Examples of metal precursors that comprise aluminum, include, but are not limited to, aluminum trichloride (AlCl₃), aluminum tribromide (AlBr₃), aluminum triiodide (AlI₃), trimethyl aluminum (AlMe₃), triethyl aluminum (AlEt₃), bis(tertbutyl)methylaluminium (^{t}Bu₂AlMe), triisobutylaluminium (Al(ⁱBu)₃), trineopentylaluminium (Al(ⁿPe)₃), dimethylaluminum hydride (AlHMe₂), aluminum methoxide (Al(OMe)₃), aluminum ethoxide (Al(OEt)₃), aluminum isopropoxide (Al(OⁱPr)₃), dimethylaluminum iso-propoxidealuminum (AlMe₂OⁱPr), dimethylaluminum chloride (AlMe₂Cl), tris(dimethylamino)aluminum Al(NMe₂)₃, tris(diethylamino)aluminum (Al(NEt₂)₃), diethyl-(N,N′-diisopropylamidinato)aluminum (Al(ⁱPrAMD)Et₂), 3-(dimethylamino)propylaluminium (Al(DMP)₃), tris(1-dimethylamino-2-methyl-2-propoxy)aluminum (Al(dmamp)₃), tri(1-methoxy-2-methyl-2-propoxy)aluminum (Al(mmp)₃), dimethyl-3-(dimethylamino)propylaluminum (AlMe₂(DMP)), bis-(diisopropylamido)(3-dimethylamino)propylaluminum (Al(NⁱPr₂)(DMP)), tris(N,N′-diisopropyl-2-dimethylamidoguanidinato)aluminum (Al(dpguan)₃), tris(neopentyl)aluminum (Al(ⁿPe)₃), and aluminum acetylacetonate (Al(acac)₃). Examples of metal precursors that comprise gallium, include, but are not limited to, gallium trichloride (GaCl₃), gallium tribromide (GaBr₃), gallium triiodide (Gal₃), trimethylgallium (GaMe₃), triethylgallium (GaEt)₃, trineopentylgallium (Ga(ⁿPe)₃), gallium acetylacetonate (Ga(acac)₃), tris-2,2,6,6-tetramethyl-heptane-3,5-dione gallium (Ga(thd)₃), tris(1-dimethylamino-2-methyl-2-propoxy)gallium (Ga(dmamp)₃), tris(1,3-diisopropyltriazenide)gallium (Ga(triaz)₃), dimethylethylgallium (GaEtMe₂), tris(N,N′-diisopropylamidinato)gallium (Ga(ⁱPrAMD)₃), tris(N,N′-diisopropylformamidinato)gallium (Ga(ⁱPrFMD)₃), and diethyl-bis(trimethylsilyl)amino gallium (Ga(N(SiMe₃)₂)Et₂). Examples of metal precursors that comprise indium, include, but are not limited to, trimethylindium (InMe₃), triethylindium (InEt₃), dimethylethylindium (InEtMe₂). trineopentylindium (In(ⁿPe)₃), dimethylindium chloride (InClMe₂), indium trichloride (InCl₃), indium tribromide (InBr₃), indium triiodide (InI₃), indium acetylacetonate (In(acac)₃), tris(dimethylamino-2-methyl-2-propoxy)indium (In(dmamp)₃, (isopropoxide)bis(dimethylamino-2-methyl-2-propoxy)indium (In(dmamp)₂(OⁱPr)), ethylcyclopentadienylindium (ln(EtCp)), 1-methylbutylcyclopentadienylindium (In(Cp(Me)(Bu))), tris(N,N′-diisopropylformamidinato)indium (ln(ⁱPrFMD)₃, tris(N,N′-diisopropylamidinato)indium (In(iPrAMD)₃), diethyl [bis(trimethylsilyl)amido]indium (ln(N(SiMe₃)₂)Et₂), tris-2,2,6,6-tetramethyl-heptane-3,5-dione indium (In(thd)₃), tris(1,3-diisopropyltriazenide)indium (ln(triaz)₃), dimethyl(N-ethoxy-2,2-dimethylpropanamido) indium (InMe₂(edpa)), dimethyl-(N-(tert-butyl)-2-methoxy-2-methylpropan-1-amine) indium (InMe₂(N^{t}Bu(CH₂)(CH₃)₂OMe), trimethyl-(N-(tert-butyl)-2-methoxy-2-methylpropan-1-amine) indium (InMe₂(N^{t}Bu(CH₂)(CH₃)₂OMe), and tris(N,N′-diisopropyl-2-dimethylamidoguanidinato)indium (ln(dpguan)₃). Other metal precursors comprising boron, aluminum gallium, or indium are known in the art. One of skill in the art will recognize other group 13 element ligand combinations that are suitable for the methods disclosed herein.

In some embodiments, the metal precursor comprises a group 9 element. For instance, the metal in the metal precursor may be selected from cobalt (Co), rhodium (Rh), iridium (Ir), and combinations and mixtures thereof. Examples of group 9 metal precursors include cobalt precursors, such as, Bis(1,4-di-t-butyl-1,3-diazabutadienyl)cobalt(II) [Co(DAD)₂], cobalt silylamides, and cobalt carbonyls, for example. Further examples of group 9 metal precursors include iridium precursors, such as, iridium (III) acetylacetonate (Ir(acac)₃), as well as iridium (III) cyclopentadienyl (IrCp) complexes. Yet further examples of group 9 metal precursors include rhodium precursors, such as Rh(acac)₃, also known as Rhodium (III) acetylacetonate, for example.

### Nitrogen Precursors

In some embodiments, the nitrogen precursor can comprise one or more of ammonia (NH₃), hydrazine (N₂H₄), other nitrogen and hydrogen-containing gases (e.g., a mixture of nitrogen gas and hydrogen gas), and the like. The nitrogen precursor can include or consist of nitrogen and hydrogen. In some cases, the nitrogen precursor does not include diatomic nitrogen. In some embodiments, the nitrogen precursor comprises a substituted hydrazine compound. In such embodiments, the substituted hydrazine compound may comprise an alkyl-hydrazine selected from the group consisting of: tertbutylhydrazine (C₄H₉N₂H₃), methylhydrazine (CH₃NHNH₂), dimethylhydrazine (C₂H₈N₂) and diethylhydrazine (C₄H₁₂N₂). In some embodiments, the substituted hydrazine compound may comprise one or more of 1,1-diethylhydrazine, 1-ethyl-1-methylhydrazine, isopropylhydrazine, phenylhydrazine, 1,1-diphenylhydrazine, 1,2-diphenylhydrazine, N-methyl-N-phenylhydrazine, 1,1-dibenzylhydrazine, 1,2-dibenzylhydrazine, 1-ethyl-1-phenylhydrazine, 1-methyl-1-(m-tolyl)hydrazine, and 1-ethyl-1-(p-tolyl)hydrazine.

### Layer Thicknesses

The thickness of the one or more layers of the metal, phosphorus, and nitrogen layer structures of the present disclosure is not particularly limited. As used herein, the “thickness” may be an average thickness measured over a defined area of the film. Typically, the thickness of the each of the one or more layers of the metal, phosphorus, and nitrogen layer structures is between about 0.1 nm and about 100 nm, typically between about 0.1 nm and about 50 nm, or more typically between about 0.1 nm and about 10 nm.

In certain embodiments, however, each of the one of more layers of the metal, phosphorus, and nitrogen layer structures has only a very thin layer of the material which can be desirable or allowable due to the dimensions of a semiconductor device structure. Thin layers of material may be desirable for many electronics applications, including affecting work function and/or threshold voltage adjustment in transistors, and such thin layers may possess different properties when compared to thicker or bulk material layers of the material. In these embodiments, the one or more layers may be continuous and uniform; or alternatively, the layer may be discontinuous. In these embodiments, the average thickness of each of the one or more layers of the metal, phosphorus, and nitrogen layer structures may be about 0.1 nm or more to about 2 nm or less, preferably about 0.1 nm or more to about 1 nm or less. In some embodiments, the thickness of each of the one or more layers of the metal, phosphorus, and nitrogen layer structures is about 0.1, or about 0.2 nm, or about 0.3 nm, or about 0.4 nm, or about 0.5 nm, or about 0.6 nm, or about 0.7 nm, or about 0.8 nm, or about 0.9 nm, or about 1 nm, or about 1.1 nm, or about 1.2 nm, or about 1.3 nm, or about 1.4 nm, or about 1.5 nm, or about 1.6 nm, or about 1.7 nm, or about 1.8 nm, or about 1.9 nm, or about 2 nm, or any intermediate thickness between about 0.1 nm and about 2 nm or a narrower range of any two thickness within. In some embodiments, the thickness of each of the one or more layers of the metal, phosphorus, and nitrogen layer structures is less than about 2 nm, or less than about 1.9 nm, or less than about 1.8 nm, or less than about 1.7 nm, or less than about 1.6 nm, or less than about 1.5 nm, or less than about 1.4 nm, or less than about 1.3 nm, or less than about 1.2 nm, or less than about 1.1 nm, or less than about 1 nm, or less than about 0.9 nm, or less than about 0.8 nm, or less than about 0.7 nm, or less than about 0.6 nm, or less than about 0.5 nm, or less than about 0.4 nm, or less than about 0.3 nm, or less than about 0.2 nm, or less than about 0.1 nm.

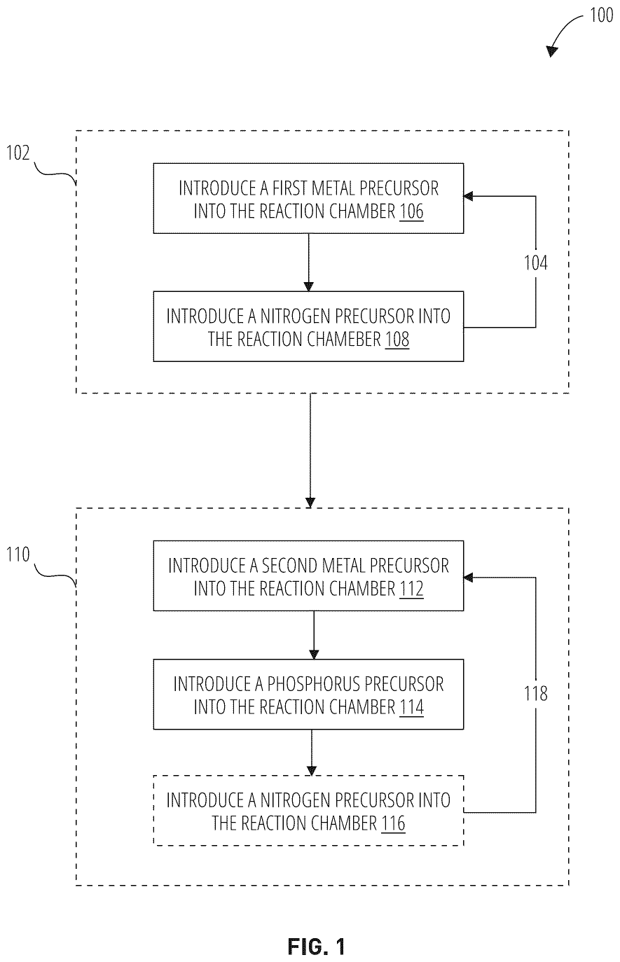

Turning now to the figures, FIG. 1 illustrate an atomic layer deposition process 100 for forming a metal, phosphorus, and nitrogen layer structure on a substrate. In brief, atomic layer deposition process 100 comprises, optionally forming a surface layer on the substrate by an initial atomic layer deposition process 102 and depositing a metal and phosphorus containing layer or a metal, phosphorus, and nitrogen containing layer on the substrate by an atomic layer deposition process 110.

In accordance with examples of the disclosure, atomic layer deposition process 100 includes the step of seating a substrate within a reaction chamber. In such examples, the reaction chamber employed for forming the metal, phosphorus, and nitrogen layer structure is constructed and arranged for performing atomic layer deposition processes (ALD). In other examples, the reaction chamber employed is constructed and arranged for performing cyclical chemical vapor deposition (CCVD) processes. In other examples, the reaction chamber employed is constructed and arranged for performing hybrid ALD/CCVD processes. In some embodiments, the reaction chamber is a standalone reaction chamber or part of a cluster tool. In some embodiments, the reaction chamber is a batch processing tool. In some embodiments, a flow-type reactor can be utilized. In some embodiments, a showerhead-type reactor can be utilized. In some embodiments, a space divided reactor can be utilized. In some embodiments, a high-volume manufacturing-capable single wafer reactor may be utilized. In other embodiments, a batch reactor comprising multiple substrates can be utilized. For embodiments in which a batch reactor is used, the number of substrates may be in the range of 10 to atomic layer deposition process 500, or 50 to 150, or even 100 to 130. The reactor can be configured as a thermal reactor—with no plasma excitation apparatus. Alternatively, the reactor can include direct and/or remote plasma apparatus.

In accordance with examples of the disclosure, the substrate disposed within the reaction chamber is heated to a desired deposition temperature for the deposition processes. In such examples, the substrate is heated to a substrate temperature of less than 400° C., less than 350° C., less than 300° C., less than 250° C., or less than 200° C. In some embodiments of the disclosure, the substrate temperature may be greater than room temperature, between 400° C. and 200° C., or between 350° C. and 250° C., or between 325° C. and 275° C.

In addition to controlling the temperature of the substrate, the pressure in the reaction chamber may also be regulated to enable deposition of the metal and phosphorus containing layer. For example, in some embodiments of the disclosure, the pressure within the reaction chamber may be less than 760 Torr, or between 0.1 Torr and 10 Torr, or between 0.5 Torr and 5 Torr, or between 1 Torr to 4 Torr.

### Deposition of an In-Situ/Ex-Situ Surface Layer (for Example TiN)

In accordance with examples of the disclosure, an optional surface layer can be deposited on the substrate prior to the deposition of a metal and phosphorus containing layer or a metal, phosphorus, and nitrogen containing layer on the substrate. In one aspect, the surface layer is deposited on the substrate employing an initial atomic layer deposition process 102 prior to seating the substrate within the reaction chamber. In another aspect, the substrate is seated within the reaction chamber and subsequently the surface layer is deposited on the substrate employing the initial atomic layer deposition process 102.

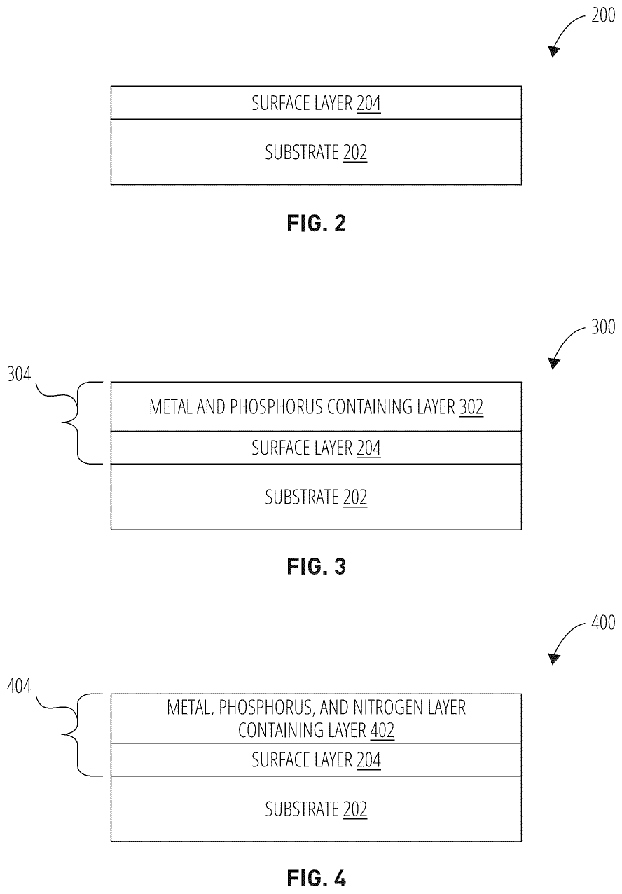

FIG. 2 illustrates a structure 200 which includes a substrate 202 (as previously described) having a surface layer 204 disposed thereon. In some embodiments, the surface layer 204 can comprise one of more of a surface semiconductor layer, a surface dielectric layer, and a surface metal layer, such as a metal, a metal nitride, a metal oxide, a metal carbide, a metal sulfide, and alloys and mixtures thereof, and the like.

In some embodiments, the surface layer 204 can comprise a metal nitride surface layer. For example, the metal nitride surface layer can comprise one or more of the metal nitride layers described above. In various examples, the metal nitride surface layer may comprise a nitride of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof. In particular examples, the metal nitride surface layer is selected from a titanium nitride surface layer, a molybdenum nitride surface layer, a cobalt nitride surface layer, and a vanadium nitride surface layer.

In various embodiments, the atomic layer deposition process 100 (FIG. 1) can include an initial atomic layer deposition process 102 for depositing the metal nitride surface layer on the substrate (e.g., substrate 202 of FIG. 2). In various embodiments, the initial atomic layer deposition process 102 comprises, sequentially and alternately introducing a first metal precursor (step 106) and a nitrogen precursor (step 108) into the reaction chamber.

In greater detail, the initial atomic layer deposition process 102 can comprise introducing a first metal precursor into the reaction chamber to form an absorbed metal species on the surface of the substrate (step 106), and introducing a nitrogen precursor into the reaction chamber to react with the metal species (step 108) to form the metal nitride surface layer on the substrate. Steps 106 and 108 can be repeated as illustrated by initial cycle loop 104. Further, steps 106 and 108 can be initiated and/or terminated in any order. Yet further, the initial atomic layer deposition process 102 can include one or more (e.g., 1-10 or 1-5) steps 106 and/or 108 prior to proceeding to the other of step 106 or 108.

In accordance with examples of the disclosure, during step 106 (and/or step 108), the first metal precursor is pulsed into the reaction chamber. The term “pulse” can be understood to comprise feeding a precursor into the reaction chamber for a predetermined amount of time. Unless otherwise noted, the term “pulse” does not restrict the length or duration of the pulse, and a pulse may be any length of time. The first metal precursor may be supplied to the reaction chamber along with a carrier gas flow. In some embodiments, the first metal precursor may comprise a volatile metal species that is reactive with the surfaces(s) of the substrate and/or the surface layer. The first metal precursor pulse may self-saturate the substrate surfaces such that excess constituents of the first metal precursor pulse do not further react with the molecular layer formed by this process. The first metal precursor is preferably supplied as a vapor phase reactant. The first metal precursor may be considered “volatile” for the purposes of the present disclosure if the species exhibits sufficient vapor pressure under the process conditions to transport species to the substrate surface in sufficient concentration to saturate the exposed surfaces.

In some cases, a purge can be employed to remove any excess precursor and/or reaction byproducts from a reaction chamber—e.g., after a precursor pulse (e.g., after step 106 and/or after step 108) and/or at a initiation and/or completion of a deposition cycle (e.g., as indicted by the initial cycle loop 104). The purge can be as described above.

In various embodiments, the initial atomic layer deposition process 102 may be initiated by introducing the first metal precursor (step 106) thereby forming a plurality of metal species on the surface of the substrate, and may subsequently continue by introducing the nitrogen precursor into the reaction chamber wherein the nitrogen precursor with the plurality of metal species to form the metal nitride surface layer on the substrate (step 108). In accordance with examples of the disclosure, the steps 106 and 108 (and any intervening purge sequences) may constitute a deposition cycle and a deposition cycle may be repeated one or more times to deposit a metal nitride surface layer to a desired thickness and composition over the substrate. A deposition cycle may be repeated multiple times, the number of repetitions being decided based on, for example, the desired thickness of the metal nitride surface layer to be deposited. For example, if the thickness of the metal nitride surface layer is less than desired for a particular application, then the step of introducing a first metal precursor into the reaction chamber (step 106), and the step of introducing a nitrogen precursor (step 108), can be repeated one or more times. Once the metal nitride surface layer has been deposited to a desired thickness/composition, the substrate can be subjected to atomic layer deposition process 110 to deposit a metal and phosphorus containing layer, or a metal, phosphorus, and nitrogen layer directly on the metal nitride surface layer.

In various embodiments, the surface layer 204 comprises a metal nitride surface layer which is deposited at a low temperature (i.e., a low deposition temperature/substrate temperature). In a particular example, the metal nitride surface layer may comprise a titanium nitride surface layer deposited at a substrate temperature lower than that commonly employed for the deposition of such layers. For example, common ALD processes employed for the deposition of titanium nitride layers are performed at a substrate temperature between 425° C. and 550° C., whereas the initial atomic layer deposition process 102 of the present disclosure may employ substrate temperatures below 400° C. In such embodiments, the metal nitride layer can be deposited at a substrate temperature of less then 400° C., less than 350° C., less than 250° C., or less 200° C. In some embodiments of the disclosure, the substrate temperature employed for the deposition of the surface layer (e.g., a metal nitride surface layer) may be greater than room temperature, between 400° C. and 200° C., between 350° C. and 250° C., or between 325° C. and 275° C.

In various embodiments, the surface layer 204 may be deposited employing any one or more of the metal precursors described above. In some embodiments, the first metal precursor is a metal halide precursor. As a non-limiting example, the initial atomic layer deposition process 102 may comprise introducing one or more of a metal chloride precursor, a metal iodide precursor, a metal bromide, and a metal fluoride precursor during step 106. As a non-limiting examples, the first metal precursor introduced into the reaction chamber in step 106 comprises an initial metal halide precursor and the surface layer comprises a metal nitride surface layer having an exposed surface which is a halide rich surface. In various embodiments, the low temperature deposition of the surface layer (e.g., a metal nitride surface layer) employing an initial metal halide precursor can form a metal nitride surface layer having an excess of halide species on exposed surfaces. As used herein the term “halide rich surface” can may refer to a surface characterized by a high concentration of a halide elements or compounds, resulting from the deposition process. As a non-limiting example, a titanium nitride surface layer deposited using a chlorine precursor (e.g., TiCl₄) may exhibit a chlorine-rich surface due to the residual chlorine atoms formed on exposed surfaces of the surface layer by the low temperature deposition process. In various embodiment, a halide rich surface (e.g., a chlorine rich surface) may be promoted by terminating the initial atomic layer deposition process 102 with the step of introducing the first metal precursor into the reaction chamber (step 108).

In various embodiments, the surface layer 204 may be deposited to a layer thickness as described above. In particular embodiments, the surface layer is deposited to a thickness between 0.1 nm and 2 nm.

### Deposition of Metal, Phosphor (and Optional) Nitrogen Layer

In various embodiments, the ALD process 100 comprises a further atomic layer deposition process 110. The atomic layer deposition process 110 can comprise a plurality of deposition cycles, each deposition cycle comprising: introducing a second metal precursor into the reaction chamber (step 112), introducing a phosphorus precursor into the reaction chamber (step 114), and optionally introducing a nitrogen precursor into the reaction chamber (step 116).

In various embodiments, steps 112, 114 and optionally 116 can be repeated as illustrated by cycle loop 118. Further, steps 112, 116, and optionally 116 can be initiated and/or terminated in any order. Yet further atomic layer deposition process 110 can include one or more (e.g., 1-10 or 1-5) steps 112, and/or 114, and/or optionally 116 prior to proceeding to the other of step 112, 114 or 116.

In accordance with examples of the disclosure, the steps 112, 114, and optionally 116 (and any intervening purge sequences) may constitute a deposition cycle and a deposition cycle may be repeated one or more times to deposit a metal and phosphorus containing layer, or metal, phosphorus, and nitrogen containing layer to a desired thickness and composition over the substrate. A deposition cycle may be repeated multiple times (as indicated by cycle loop 118), the number of repetitions being decided based on, for example, the desired thickness of the metal and phosphorus containing layer, or the metal, phosphorus, and nitrogen containing layer to be deposited and/or the degree of voltage shift desired in a semiconductor device structure, e.g., the desired thickness/composition of the deposited layer via ALD process 110. For example, if the thickness of layer deposited by ALD process 110 is less than desired for a particular application, then the step of introducing the second metal precursor into the reaction chamber (step 112), the step of introducing a phosphorus precursor into the reaction chamber (step 114), and optionally the step of introducing a nitrogen precursor into the reaction chamber (step 116) can be repeated one or more times. Once the metal and phosphorus containing layer, or the metal, phosphorus, and nitrogen containing layer has been deposited to a desired thickness/composition, the substrate can be subjected to additional processes to form a desired structure and/or device, such as, a metal-oxide-semiconductor device, for example, as described below.

In some embodiments, atomic layer deposition process 110 comprises performing one or more deposition cycles, each deposition cycle comprising: introducing the second metal precursor into the reaction chamber (step 106), and introducing the phosphorus precursor into the reaction chamber (step 108), as well as any intervening purge sequences. In such embodiments, the atomic layer deposition process 110 is employed to deposit a metal and phosphorus containing layer (e.g., a metal phosphide layer). For example, FIG. 3 illustrates a structure 300 including a substrate 202, a surface layer 204 disposed on the surface of the substrate 202, and a metal and phosphorus containing layer 302 deposited on the surface layer 204 by the processes described herein. In various embodiments, the metal and phosphorus containing layer 302 may be deposited to a layer thickness as described above. In particular embodiments, the metal and phosphorus containing layer 302 is deposited to a thickness between 0.1 nm and 2 nm. In some examples, the surface layer 204 and the metal and phosphorus containing layer 302 together form a metal, phosphorus, and nitrogen layer structure 304.

In some embodiments, atomic layer deposition process 110 comprises performing one or more deposition cycles, each deposition cycle comprising: introducing the second metal precursor into the reaction chamber (step 106), introducing the phosphorus precursor into the reaction chamber (step 108), and introducing the nitrogen precursor into the reaction chamber (step 116) as well as any intervening purge sequences. In such embodiments, the atomic layer deposition process 110 is employed to deposit a metal, phosphorus, and nitrogen containing layer (e.g., a metal phosphorus nitride layer). For example, FIG. 4 illustrates a structure 400 including a substrate 202, a surface layer 204 disposed on the surface of the substrate 202, and a metal, phosphorus, and nitrogen layer containing layer 402 deposited on the surface layer 204 by the processes described herein. In various embodiments, the metal, phosphorus, and nitrogen layer containing layer 402 may be deposited to a layer thickness as described above. In particular embodiments, the metal, phosphorus, and nitrogen layer containing layer 402 is deposited to a thickness between 0.1 nm and 2 nm. In some examples, the surface layer 204 and the metal, phosphorus, and nitrogen layer containing layer 402 together form a metal, phosphorus, and nitrogen layer structure 404.

In various embodiments, the metal, phosphorus, and nitrogen layer structures provided may comprise one or more metal, phosphorus, and nitrogen containing layers, such as metal phosphorus nitride layers. In one aspect, the one or more metal phosphorus nitride layers may be deposited directly on the substrate without an intervening surface layer. In another aspect, the one or more metal phosphorus nitride layers may be deposited directly on a surface layer disposed on the substrate.

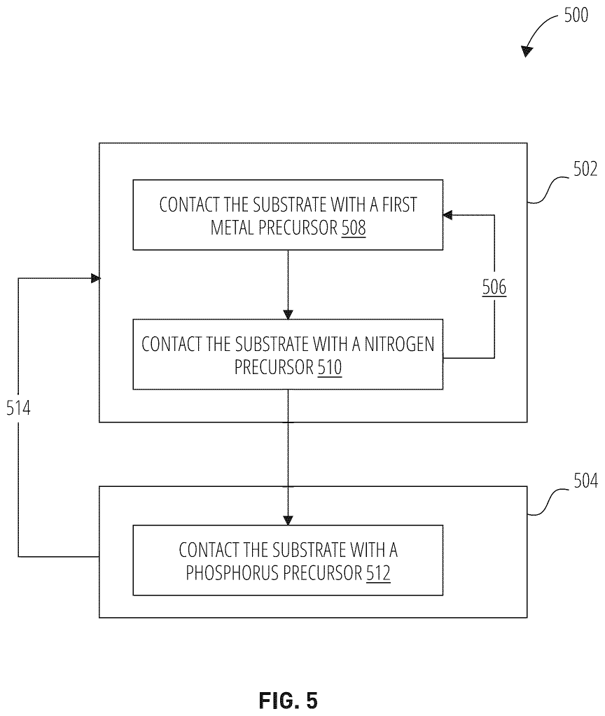

As a non-limiting example, FIG. 5 illustrates an atomic layer deposition process 500 for forming a metal, phosphorus, and nitrogen containing layer. In brief, atomic layer deposition process 500 may form a metal, phosphorus, and nitrogen containing layer (e.g., a metal phosphorus nitride layer) by initial depositing a metal and nitrogen containing layer (e.g., a metal nitride layer), and subsequently contacting the metal and nitrogen containing layer with a phosphorus precursor, where the phosphorus precursor reacts with the metal and nitrogen containing layer to form the metal, phosphorus, and nitrogen containing layer.

In greater detail, the atomic layer deposition process 500 comprises, performing one or more nitride sub-cycles (502) to deposit a metal nitride layer on the substrate. The process steps of the nitride sub-cycle 502 can the same, or substantially the same, as the initial atomic layer deposition process 102 including the steps, precursors, and structures formed as described above. For example, each deposition cycle of the nitride sub-cycle 502 can comprise, contacting the substrate with a first metal precursor (step 508), and contacting the substrate with a nitrogen precursor (step 510). In various embodiments, step 508, and step 510 can be repeated as illustrated by first cycle loop 506. Further, steps step 508, and step 510 can be initiated and/or terminated in any order. Yet further, nitride sub-cycle 502 can include performing one or more (e.g., 1-10 or 1-5) step 508 and/or optionally 510 prior to proceeding to the other of step 508, or 510.

In addition, the nitride sub-cycle 502 can include intervening purge sequences before and after each step, and or before or after the completion of each deposition cycle. In certain embodiments, having performed the desired number of deposition cycles of the nitride sub-cycle 502, the nitride sub-cycle may be terminated by introducing (and/or reintroducing) the first metal precursor into the reaction chamber (step 508). In particular examples, the first metal precursor comprises a first metal halide precursor. For example, the first metal halide precursors may comprise one or more of the metal halide precursors as described previously. In such examples, terminating the nitride sub-cycle 502 by introducing the first metal halide precursor can enable the formation of a metal nitride layer with a halide rich surface, as previously described.

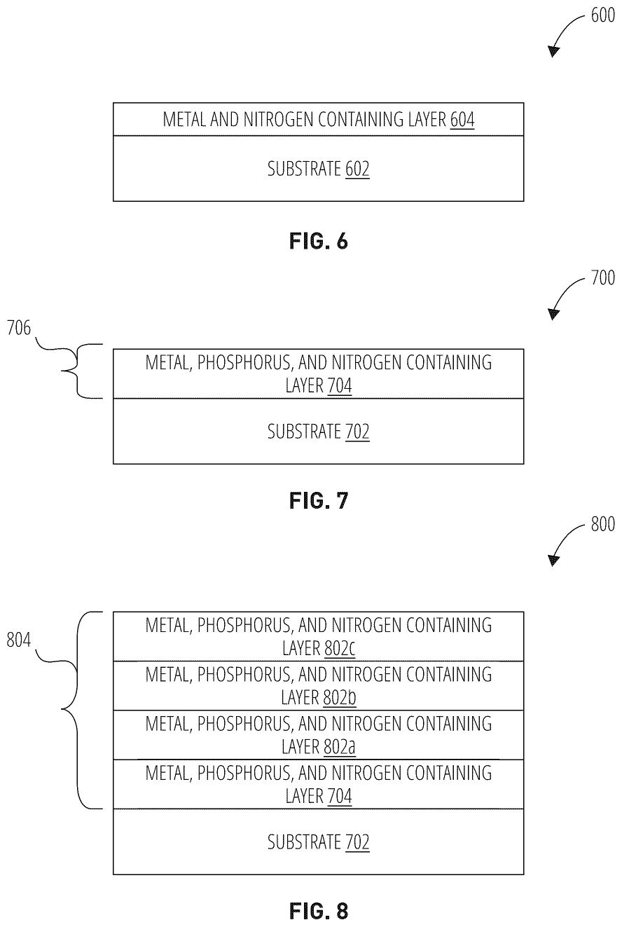

FIG. 6 illustrates a structure 600 including a substrate 602 and a metal and nitrogen containing layer 604 deposited on the substrate 602 by the processes described herein. In various embodiments, the metal and nitrogen containing layer 604 may be deposited to a layer thickness as described above. In particular embodiments, the metal and nitrogen containing layer 604 is deposited to a thickness between 0.1 nm and 2 nm. In some examples, the metal and nitrogen containing layer 604 comprises a metal nitride layer, as described above.

In various embodiments, atomic layer deposition process 500 (FIG. 5) can comprise contacting the substrate with a phosphorus precursor (step 512), which may be referred to herein as a phosphide sub-cycle 504. In various examples, the step of contacting the substrate with the phosphorus precursor (step 512) is performed after the completion of the nitride sub-cycle 502 employed for the deposition of a metal and nitrogen containing layer on the substrate. In various embodiments, the step of contacting the substrate with the phosphorus precursor (step 512) forms a metal, phosphorus, and nitrogen containing layer by the reaction between the phosphorus precursor and the metal and nitrogen containing layer formed during the nitride sub-cycle 502. In one aspect the step of contacting the surface with the phosphorus precursor (step 512) is performed after having performed the step of contacting the surface of the substrate with the first metal precursor (step 508). The phosphide sub-cycle 504 can be repeated one or more times prior to terminating the phosphide sub-cycle 504. The phosphorous precursor introduced in step 512 of atomic layer deposition process 500 may comprise one or more of the phosphorus precursors described above.

FIG. 7 illustrates a structure 700 including a substrate 702 and a metal, phosphorus, and nitrogen containing layer 704 deposited on the substrate 702 by the processes described herein. In various embodiments, the metal, phosphorus, and nitrogen containing layer 704 may be deposited to a layer thickness as described above. In particular embodiments, the metal, phosphorus, and nitrogen containing layer 704 is deposited to a thickness between 0.1 nm and 2 nm. In some examples, the metal, phosphorus, and nitrogen containing layer 704 comprises the metal, phosphorus, and nitrogen layer structure 706, as described above. In some embodiments, the metal, phosphorus, and nitrogen containing layer 704 comprise one or more metals as described above. In particular examples, the metal, phosphorus, and nitrogen containing layer 704 comprises a metal selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

In various embodiments, the sequence of performing one or more nitride sub-cycles 502 and performing one or more phosphide sub-cycles 504 can it itself be repeated as a super-cycle deposition process, as indicated by the super-cycle loop 514. In such embodiments, atomic layer deposition process 500 can include one or more repeated deposition super-cycles, where each deposition super-cycle comprises, performing one or more nitride sub-cycles 502 and subsequently performing one or more phosphide sub-cycles 504. A deposition super-cycle can be repeated one or more times (as indicated by the super-cycle loop 514) until a metal, phosphorus, and nitrogen containing layer is deposited to a desired thickness and composition.

In some embodiments the composition of the metal, phosphorus, and nitrogen containing layer and layers structures formed therefrom deposited by atomic layer deposition process 500, may be tuned by adjusting the ratio of the number of repetitions of the nitride sub-cycles 502 compared with the number of repetitions of the phosphide sub-cycles 504 within one or more individual deposition super-cycles. As a non-limiting example, a desired composition of a metal phosphorus nitride layer may be achieved by selecting the number of times each sub-cycle (e.g., sub-cycles 502, and 504) are repeated to deposited a metal phosphorus nitride layer with a desired metal:phosphorus:nitrogen (M:P:N) composition ratio.

FIG. 8 illustrates a structure 800 including the substrate 702 and the metal, phosphorus, and nitrogen containing layer 704 deposited on the substrate 702 by the processes described herein and described previously with reference to FIG. 7. As illustrated in FIG. 8, structure 800 further comprises multiple metal, phosphorus, and nitrogen containing layers (802a, 802b, 802c) deposited by repeatedly performing the deposition super-cycle as described above. In some examples, the metal, phosphorus, and nitrogen containing layer 704, as well as the additional metal, phosphorus, and nitrogen containing layers (802a, 802b, 802c) together comprise the metal, phosphorus, and nitrogen layer structure 804. In particular examples, the metal, phosphorus, and nitrogen containing layers 704, 802a, 802b, and 802c comprise one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof. Although FIG. 8 illustrates a metal, phosphorus, and nitrogen layer structure 804 comprising four (4) metal, phosphorus, and nitrogen containing layers, it should be appreciated that the processes and structures provided are not limited as such, and that the metal, phosphorus, and nitrogen layer structure 804 provided may comprise any number of metal, phosphorus, and nitrogen containing layers as is desired.

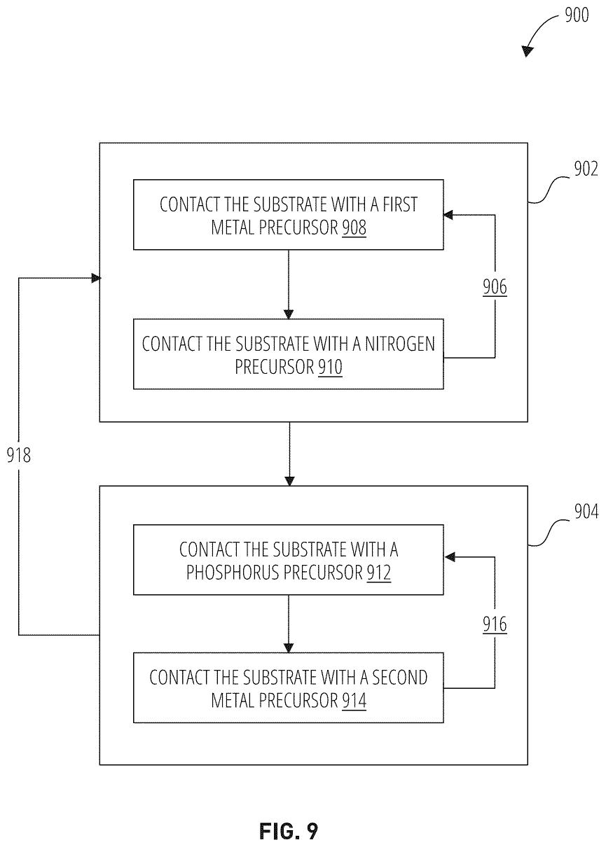

FIG. 9 illustrates an atomic deposition process comprising a super-cycle deposition process 900 for depositing a metal, phosphorus, and nitrogen layer structure. In various embodiments, the super-cycle deposition process 900 comprises, performing one or more deposition super-cycles (as indicated by super-cycle loop 918), each deposition super-cycle comprising one or more nitride sub-cycles 902 and one or more phosphide sub-cycles 904.

In various embodiments, performing one or more nitride sub-cycles 902 deposits one or more metal and nitrogen containing layers (e.g., one or more metal nitride layers). In some embodiments, performing one or more phosphide sub-cycles 904 deposits one or more metal and phosphorus containing layers (e.g., one or more metal phosphide layers). In some embodiments, the metal, phosphorus, and nitrogen layer structures formed by the super-cycle deposition process 900 comprise one or more metal nitride layers and one or more metal nitride layers. In some embodiments, the metal, phosphorus, and nitrogen layer structures formed by the super-cycle deposition process 900 comprise one or more metal phosphorus nitride layers.

The nitride sub-cycle 902 of super-cycle deposition process 900 can be the same, or substantially the same, as the previously described nitride sub-cycle 502 of FIG. 5. In some embodiments, the nitride sub-cycle 902 comprises, contacting the substrate with a first metal precursor (step 908), and contacting the substrate with a nitrogen precursor (step 910). The nitride sub-cycle 902 can be repeated one or more times (as indicated by the first cycle loop 906) until a desired thickness of a metal and nitrogen containing layer (e.g., a metal nitride) is deposited. In various embodiments, step 908 and step 910 can be initiated and/or terminated in any order. Further, the nitride sub-cycle 902 can include performing one or more (e.g., 1-10 or 1-5) step 908 and/or step 910 prior to proceeding to the other of step 908, or step 910. In addition, the nitride sub-cycle 902 can include intervening purge sequences before and after each step, and or before or after the completion of deposition cycle. In certain embodiments, the nitride sub-cycle 902 may be terminated by performing step 908 to enable the formation of a metal nitride layer with a halide rich surface, as previously described. For example, step 908 may comprise contacting the substrate with a first metal precursor comprising a first metal halide precursor (e.g., a metal chloride precursor).

In various embodiments, super-cycle deposition process 900 further comprises performing one or more deposition cycles of a phosphide sub-cycle 904. In some embodiments, the phosphide sub-cycle 904 comprises, contacting the substrate with a phosphorus precursor (step 912), and contacting the substrate with a second metal precursor (step 914). The phosphide sub-cycle 904 can be repeated one or more times (as indicated by the second cycle loop 916) until a desired thickness of a metal and phosphorus layer (e.g., a metal phosphide) is deposited. In various embodiments, step 912 and step 914 can be initiated and/or terminated in any order. Yet further, the phosphide sub-cycle 904 can include performing one or more (e.g., 1-10 or 1-5) step 912 and/or step 914 prior to proceeding to the other of step 912, or step 914. In addition, the phosphide sub-cycle 904 can include intervening purge sequences before and after each step, and or before or after the completion of deposition cycle.

In various embodiments, the phosphide sub-cycle 904 can include intervening purge sequences before and after each step, and or before or after the completion of each deposition cycle. In certain embodiments, the phosphide sub-cycle 904 may be initiated by introducing the second metal precursor into the reaction chamber (step 914). In particular examples, the second metal precursor comprises a second metal halide precursor. For example, the second metal precursor may comprise one or more of the metal halide precursors as described previously. In such examples, initiating the phosphide sub-cycle 904 by introducing the second metal precursor can enable the formation of an underlying metal nitride layer with a halide rich surface, as previously described.

In some embodiments, one or more of the deposition super-cycles (as indicated by super-cycle loop 918) of the super-cycle deposition process 900 can comprise initially performing one or more nitride sub-cycles 902 and subsequently performing one or more metal phosphide sub-cycles 904. In other embodiments, the super-cycle deposition process 900 can comprise initially performing one or more phosphide sub-cycles 904 and subsequently performing one or more nitride sub-cycles 902. In addition, the super-cycle deposition process 900 can include intervening purge sequences before and after each sub-cycle (902 and 904), and or before or after the completion of each deposition super-cycle.

In various embodiments, the super-cycle deposition process 900 is employed to deposit a metal, phosphorus, and nitrogen layer structure comprising a laminate structure. In one aspect, the laminate structure can comprise a metal nitride-metal phosphide laminate structure comprising a repeating unit layer structure comprising a metal nitride layer and a metal phosphide layer, the metal phosphide layer being disposed directly on the metal nitride layer (or vice versa). In another aspect, the laminate structure can comprise a metal nitride-metal phosphorus nitride layer laminate structure comprising a repeating unit layer structure comprising a metal nitride layer and a metal phosphorus nitride layer, the metal phosphorus nitride layer being disposed directly on the metal nitride layer (or vice versa).

In accordance with certain examples, the composition of the metal, phosphorus, and nitrogen layer structures deposited by super-cycle deposition process 900 may be tuned by adjusting the ratio of the number of repetitions of the nitride sub-cycle 902 compared with the number of repetitions of the phosphide sub-cycle 904 within one or more individual deposition super-cycles (referred to herein as the sub-cycle ratio). As a non-limiting example, a desired composition of a metal, phosphorus, and nitrogen layer structure may be achieved by selecting the number of times each sub-cycle (e.g., sub-cycles 902 and 904) are repeated to deposit a metal, phosphorus, and nitrogen layer structure having a desired metal:phosphorus:nitrogen (M:P:N) composition ratio.

In some embodiments, the sub-cycle ratio may be expressed as (N₁×nitride sub-cycle):(N₂×phosphide sub-cycle) where N₁ and N₂ are both a real integer. In some embodiments, the sub-cycle ratio (N₁:N₂) is 1:1, 1:2, 1:3, 1:4, 1:5, 1:6, 1:7, 1:8, 1:9, or 1:10. In some embodiments, the sub-cycle ratio (N₁:N₂) is 10:1, 9:1, 8:1, 7:1, 6:1, 5:1, 4:1, 3:1, 2:1, or 1:1.

In some embodiments, the deposited metal, phosphorus, and nitrogen layer structures provided comprise one or more layers having a stoichiometry or elemental ratio (M:P:N) of about 1:1:1, or from 0.1:1:1 to 10:1:1, or from 1:0.1:1 to 1:10:1, or from 1:1:0.1 to 1:1:10, or from 0.1:0.1:1 to 10:10:1, or from 0.1:1:0.1 to 10:1:10, or from 1:0.1:0.1 to 1:10:10. In some embodiments the metal, phosphorus, and nitrogen layer structures provided comprise one or more layers having a stoichiometry or elemental ratio (M:P:N) from 0.01:1:1 to 100:1:1, or from 1:0.01:1 to 1:100:1, or from 1:1:0.01 to 1:1:100, or from 0.01:0.01:1 to 100:100:1, or from 0.01:1:0.01 to 100:1:100, or from 1:0.01:0.01 to 1:100:100.

In various examples, super-cycle deposition process 900 includes one or more nitride sub-cycle 902 having a process step (step 908) of contacting the substrate with a first metal precursor and one or more phosphide sub-cycle 904 having a process step (step 914) of contacting the substrate with a second metal precursor. In particular examples, the first metal precursor comprises a first metal species (M₁) and the second metal metal precursor comprises a second metal species (M₂). In one aspect, the first metal species is the same as the second metal species, i.e., M₁=M₂. In another aspect, the first metal species is different to the second metal species, i.e., M₁≠M₂. In various embodiments, the first metal precursor comprises a first metal halide precursor including a first metal species (M₁), and the second metal precursor comprises a second metal halide precursor including a second metal species (M₂), where M₁=M₂ or M₁≠M₂.

In various examples, the super-cycle deposition process 900 can be employed to deposit a laminate structure comprises a repeating unit layer structure comprising a metal nitride layer including the first metal species (M₁) and a metal phosphide layer including the second metal species (M₂) disposed on the metal nitride layer (or vice versa), where M₁=M₂ or M₁≠M₂. In some embodiments, the super-cycle deposition process 900 can be employed to deposit a laminate structure comprises a repeating unit layer structure comprising a metal phosphorus nitride layer including a first metal species (M₁) and a metal nitride layer including a second metal species (M₂) disposed on the metal phosphorus nitride layer (or vice versa), where M₁=M₂ or M₁≠M₂.

In certain examples where the first metal species is different to the second metal species, i.e., M₁≠M₂, the composition of the metal, phosphorus, and nitrogen layer structures deposited by super-cycle deposition process 900 can be controlled to adjust the composition ratio of the first metal species to the second metal species (as well as the composition of phosphorus and nitrogen) in the layer structure, i.e., the ratio of M₁:M₂:P:N. In such examples, the sub-cycle ratio (N₁:N₂) is 1:1, 1:2, 1:3, 1:4, 1:5, 1:6, 1:7, 1:8, 1:9, or 1:10. In other embodiments, the sub-cycle ratio (N₁:N₂) is 10:1, 9:1, 8:1, 7:1, 6:1, 5:1, 4:1, 3:1, 2:1, or 1:1. As a non-limiting example, M₁ and M₂ may be selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

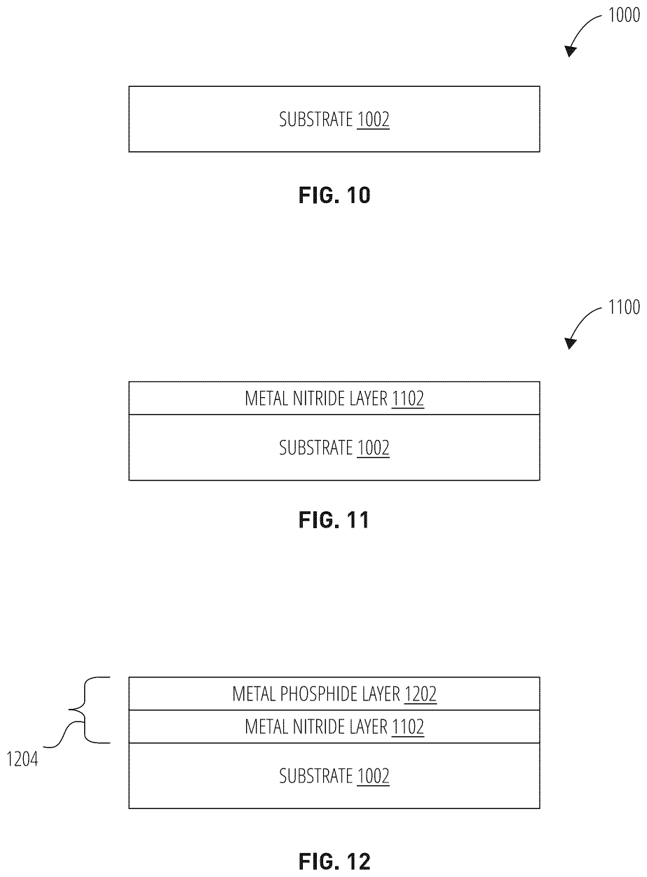

FIGS. 10-13 illustrate various structures formed by the super-cycle deposition process 900 of FIG. 9. For example, structure 1000 comprises a substrate 1002, as previously described. FIG. 11 illustrates a structure 1100 comprising the substrate 1002 and a metal nitride layer 1102 deposited by performing one or more deposition cycles of the nitride sub-cycle 902. FIG. 12 illustrates a structure 1200 comprising the substrate 1002, the metal nitride layer 1102, and a metal phosphide layer 1202 deposited by performing one or more deposition cycles of the phosphide sub-cycle 904. In some embodiments, the metal nitride layer 1102 together with the metal phosphide layer 1202 comprises a metal, phosphorus, and nitrogen layer structure 1204. In such embodiments, the deposition super-cycle is performed once to form the metal, phosphorus, and nitrogen layer structure 1204.

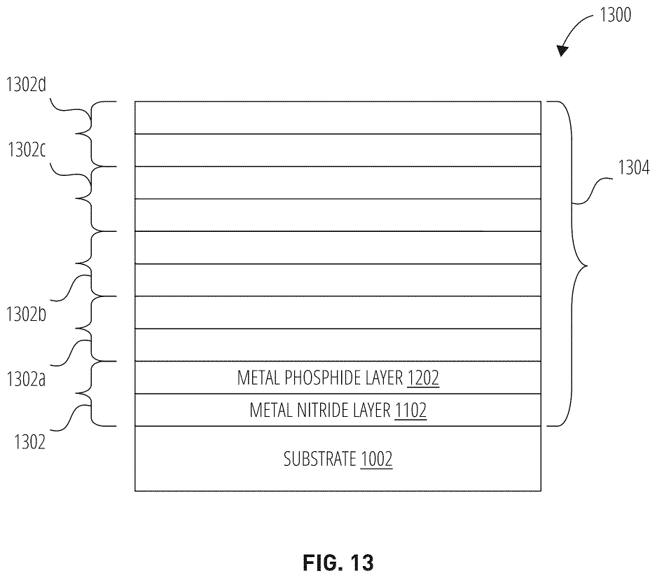

FIG. 13 illustrates a structure 1300 which comprises structure 1200 (FIG. 12) upon completion of a number of repetitions of the deposition super-cycle (as indicted by super-cycle loop 918) of the super-cycle deposition process 900. As previously described, having perform the deposition super-cycle once, the structure 1200 comprises a metal phosphide layer 1202 disposed on a metal nitride layer 1102. In certain examples, the metal phosphide layer 1202 disposed on the metal nitride layer 1102 constitutes a unit layer structure 1302 (as illustrated in FIG. 13). In the non-limiting example illustrated in FIG. 13, the unit layer structure 1302 comprise a bilayer of a metal phosphide layer 1202 and a metal nitride layer 1102. Upon repeating the deposition super-cycle of super-cycle deposition process 900 one or more times, one or more addition unit layer structures 1302a, 1302b, 1302c, 1302d, can be sequentially deposited to form a metal, phosphorus, and nitrogen layer structure 1304 comprising multiple unit layer structures. In one aspect, each of the unit layer structures of metal, phosphorus, and nitrogen layer structure 1304 comprises multiple bilayers (1302, 1302a, 1302b, 1302c, 1302c, and 1302d) having the same thickness and composition. In another aspect, one or more the unit layer structures of the metal, phosphorus, and nitrogen layer structure 1304 comprises multiple bilayers (1302, 1302a, 1302b, 1302c, 1302c, and 1302d) having the different thickness and composition.

Various embodiments of the disclosure include methods of forming at least a portion of a gate stack for semiconductor device. In particular, the metal, phosphorus, and nitrogen layer structures deposited by the various methods provided may be used as a threshold voltage shifting layer in semiconductor device structures, such as a field effect transistors. The use of the metal, phosphorus, and nitrogen layer structures as a threshold voltage shifting layer results in a shift in the effective work function of the gate electrode in the FET towards the Si conduction band in the case of n-type FETs or towards the Si valence band in the case of p-type FETs. According to some embodiments, a gate stack comprising a threshold voltage shifting layer comprising the metal, phosphorus, and nitrogen layer structures disclosed herein can have an effective work from ranging from about 4.0 eV to about 6 eV, wherein the shift in the effective work function is about 10 meV to about 400 meV, or about 30 meV to about 300 meV, or about 50 meV to about 200 meV. The thickness of the threshold voltage shifting layer comprising the metal, phosphorus, and nitrogen layer structures can be tailored to tune the shift in the effective work function and hence the threshold voltage (Vt). Accordingly, in various embodiments, a thickness of the threshold voltage shifting layer comprising the metal, phosphorus, and nitrogen layer structure may vary between about 0.01 nm and about 2 nm. Additionally, the composition of the threshold voltage shifting layer comprising the metal, phosphorus, and nitrogen layer structure (as previous described) can be tailored to tune the shift in the effective work function and hence the Vt, and/or to reduce the equivalent oxide thickness of the layer. In some embodiments, the threshold voltage shifting layer comprising the metal, phosphorus, and nitrogen layer structure has a low oxygen content or is free of oxygen. As a non-limiting example, the threshold voltage shifting layers deposited by the methods of the disclosure do not comprise, or do not substantially comprise oxygen, hence, the metal, phosphorus, and nitrogen layer structures employed as threshold voltage shifting layers may be referred to as oxygen free. The lack of, or substantial lack of, or even a low oxygen content (e.g., an oxygen content of less than about 5.0% (atomic %), or less than about 1.0%, or less than about 0.1%) in the threshold voltage shifting layers provided may beneficially to reduce the equivalent oxide thickness (EOT) of a gate dielectric stack of a metal-oxide-semiconductor FET (MOSFET).

Additionally, or alternatively, in some embodiments, the threshold voltage shifting layers provided can have a low carbon content. The lack of, or substantial lack of, or even a low carbon content (e.g., a carbon content of less than about 5.0% (atomic %), or less than about 1.0%, or less than about 0.1%) in the layers structures provided may beneficially reduce the number of defects in the film resulting in improved performance.

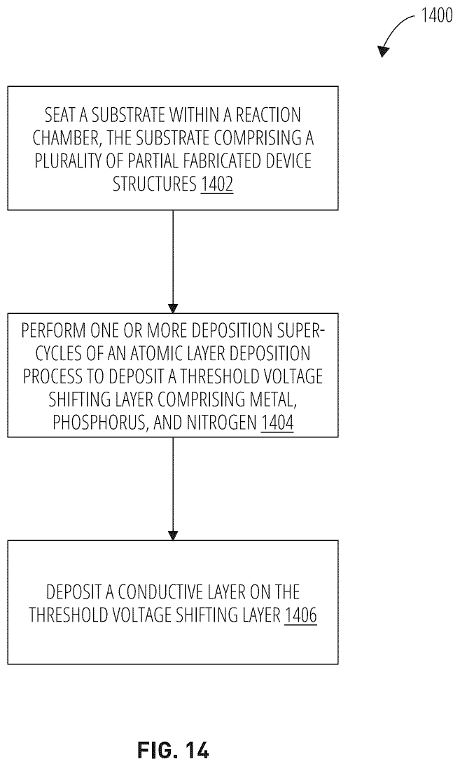

Turning again to the figures, FIG. 14 illustrates a method 1400 for forming at least a portion of a gate stack for a semiconductor device structure.

In various embodiments, method 1400 comprises, seating a substrate within a reaction chamber, the substrate comprising a plurality of partially fabricated device structures (step 1402). In some embodiments, the partially fabricated device structures include a surface layer comprising a high-k dielectric layer or a silicon oxide surface. In a particular example, the plurality of partially fabrication device structures include NMOS, PMOS, and/or CMOS structures.

In various embodiments, method 1400 comprises, performing one or more deposition cycles of an atomic layer deposition process to deposit a metal, phosphorus, and nitrogen layer structure directly on a surface of the high-k dielectric layer or the silicon oxide surface (step 1404). In some embodiments, the atomic layer deposition process comprises a super-cycle deposition process (such as super-cycle deposition process 900 of FIG. 9). In such embodiments, the super-cycle deposition process can comprise one or more the deposition super-cycles comprising: performing one or more nitride sub-cycles, each of the one or more nitride sub-cycles comprising: contacting the substrate with a first metal halide precursor, and contacting the substrate with a nitrogen precursor; and performing one or more phosphide sub-cycles, each of the one or more phosphide sub-cycles comprising; contacting the substrate with a second metal precursor; and contacting the substrate with a phosphorus precursor (as previously described above).

In various embodiments, the metal, phosphorus, and nitrogen layer structure can be deposited directly on a surface of the high-k dielectric layer or the silicon oxide surface and comprises a threshold voltage shifting layer. In such examples, the threshold voltage shifting layer may comprise one or more of the metals described previously. In particular examples, the threshold voltage shifting layer may comprise one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

In various embodiments, the threshold voltage shifting layer comprises a laminate structure. In a particular example, the laminate structure comprises a metal nitride-metal phosphide laminate structure selected from the group consisting of a titanium nitride-titanium phosphide laminate structure, a molybdenum nitride-molybdenum phosphide laminate structure, and a cobalt nitride-cobalt phosphide laminate structure. In additional embodiments, the threshold voltage shifting layer may a comprise a laminate structure composed of any one or more of the materials described previously.

In various embodiments, method 1400 comprises depositing a conductive layer on the threshold voltage shifting layer (step 1406). In some embodiments, a conductive layer is deposited directly on the threshold voltage shifting layer. In accordance with examples of the disclosure, the conductive layer can function as a conductive electrode to complete the gate stack. In such examples, the dielectric layer (e.g., the high-k dielectric layer) on the surface of the substrate functions as the gate dielectric layer (either with or without an intervening interface layer between a channel region and the gate dielectric layer), the metal, phosphorus, and nitrogen layer structure functions as the threshold voltage shifting layer, and the conductive layer functions as the gate electrode layer.

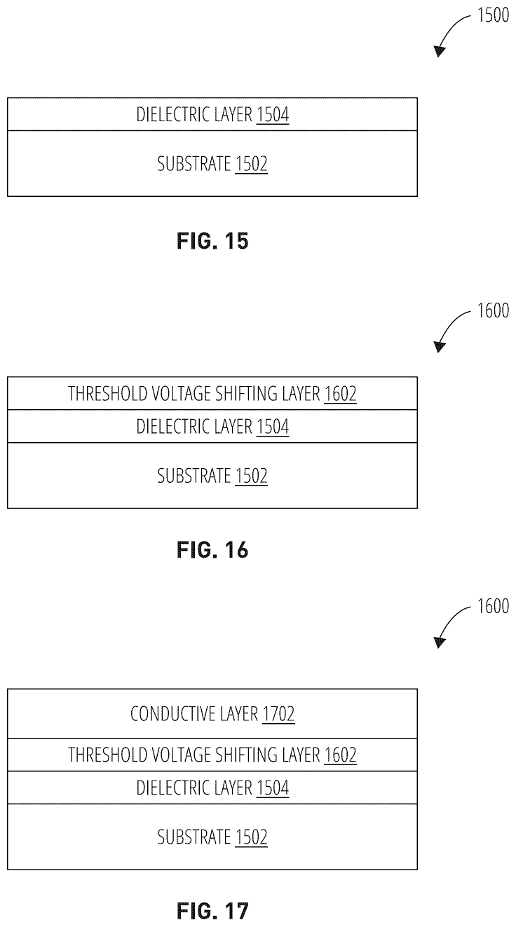

FIG. 15 illustrates a structure 1500 comprising a substrate 1502 and a dielectric layer 1504. Structure 1500 can comprise a plurality of partially fabricated device structures, such as NMOS, PMOS, and/or CMOS devices (not illustrated). In particular examples, the partially fabricated device structure comprises a surface comprising the dielectric layer 1504. In some embodiments, the dielectric layer 1504 comprises a high dielectric constant layer (i.e., a high-k dielectric layer), where the high-k dielectric layer demonstrating a dielectric constant greater than about 7. Exemplary high-k dielectric layers include, but are not limited to, hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers. In some embodiments, the dielectric layer 1504 comprises a silicon oxide layer, such as silicon oxide interface layer, for example. In some embodiments, the dielectric layer comprises one or more of a high-k dielectric layer and a silicon oxide layer.

FIG. 16 illustrates a structure 1600 comprising the structure 1500 upon the deposition of a metal, phosphorus, and nitrogen layer structure on the dielectric layer 1504, the metal, phosphorus, and nitrogen layer structure comprising a threshold voltage shifting layer 1602.

FIG. 17 illustrates a structure 1700 comprising the structure 1600 upon the deposition of a conductive layer 1702 on the threshold voltage shifting layer 1602. In some embodiments, the conductive layer 1702 can be selected from titanium nitride; vanadium nitride; a metal stack including titanium nitride and a metal (e.g., W, Co, Ru, Mo) or titanium nitride, titanium aluminum carbon, and titanium nitride; tungsten; tungsten carbon nitride; cobalt; copper; molybdenum; ruthenium; or the like.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method of forming a metal, phosphorus, and nitrogen layer structure on a substrate, the method comprising:
seating the substrate within a reaction chamber;
forming a surface layer on the substrate;
performing an atomic layer deposition process comprising a plurality of repeated deposition cycles, each deposition cycle comprising:
introducing a first metal precursor into the reaction chamber thereby forming a plurality of metal species on the surface of the substrate; and
introducing a phosphorus precursor into the reaction chamber wherein the phosphorus precursor reacts with the plurality of metal species.

2. The method of claim 1, wherein the surface layer comprises a metal nitride surface layer deposited by an initial atomic layer deposition process comprising, sequentially and alternately introducing a second metal precursor and a nitrogen precursor into the reaction chamber.

3. The method of claim 2, wherein the second metal precursor comprises an initial metal halide precursor and the metal nitride surface layer comprises a halide rich surface.

4. The method of claim 1, wherein one or more of the deposition cycles further comprises, introducing an additional nitrogen precursor into the reaction chamber.

5. The method of claim 1, wherein the atomic layer deposition process is performed at substrate temperature between 200° C. and 400° C.

6. The method of claim 1, wherein the phosphorus precursor is selected from the group consisting of phosphine (PH₃), tetraphosphorus (P₄), 1,2-diphosphinoethane (C₂H₈P₂), methyl phosphine (PH₂Me), trimethyl phosphine (PMe₃), ethyl phosphine (PH₂Et), triethyl phosphine (PEt₃), isopropylphosphine (PH₂ⁱPr), i-butylphosphine (PH₂ⁱBu), t-butylphosphine (PH₂^{t}Bu), dichloromethylphosphine (MePCl₂), dichloroethylphosphine (PCl₂Et), dichloropropylphosphine (PCl₂ⁿPr), dichloroisopropylphosphine (PCl₂ⁱPr), dichlorobutylphosphine (PCl₂ⁿBu), dichlorotertbutylphosphine (PCl₂^{t}Bu), (PClⁱPr₂), chloro(dimethyl)phosphine (PClMe₂), chloro(diethyl)phosphine (PClEt₂), chloro(di-secbutyl)phosphine (PCl^{s}Bu₂), bromo(di-secbutyl)phosphine (PBr^{t}Bu₂), chloro(di-tertbutyl)phosphine (PCl^{t}Bu₂), chloro(tertbutyl)(methyl)phosphine (PCl^{t}BuMe), cyclohexylphosphine (PH₂(C₆H₁₁), phenyl phosphine (PH₂Ph), 1,2-diphosphinobenzene, tris(N-pyrrolidinyl)phosphine, dimethylaminophosphine (PH₂(NMe₂)₂), bis(dimethylamino)phosphine (PH(NMe₂), dimethylamino(methyl)phosphine(PMe(NMe₂)₂), tris(dimethylamino)phosphine (P(NMe₂)₃), tris(diethylamino)phosphine (P(NEt₂)₃), chlorobis(dimethylamino)phosphine (PCl(NMe₂)₂), dichloro(dimethylamino)phosphine (PCl₂(NMe₂)), dichloro(diethylamino)phosphine (PCl₂(NEt₂)), chlorobis(diethylamino)phosphine (PCl(NEt₂)₂), chlorobis(diisopropylamino)phosphine (PCl(NⁱPr₂)₂), dichloro(diisopropylamino)phosphine (PCl₂(NⁱPr₂)), tris(dimethylamino)phosphine (P(═NH)(NMe₂)₃), trisilylphosphine (P(SiH₃)₃), tris(trimethylsilyl) phosphine (P(SiMe₃)₃), tris(triethylsilyl) phosphine (P(SiEt₃)₃), tris(trimethylsiloxy)phosphine (P(OSiMe₃)₃), trimethyl phosphite (POMe₃), trimethyl phosphate (P(O)OMe₃), phosphorus pentoxide (P₂O₅), phosphorous trichloride (PCl₃), phosphorous tribromide (PBr₃), phosphorous triiodide (PI₃), phosphorous pentachloride (PCl₅), phosphorous pentabromide (PBr₅), phosphoryl chloride (POCl₃), and phosphoryl bromide (POBr₃) and combinations thereof.

7. An atomic layer deposition process for depositing a metal, phosphorus, and nitrogen layer structure on a substrate seated within a reaction chamber, the atomic layer deposition process comprising:
performing one or more nitride sub-cycles, each of the one or more nitride sub-cycles comprising:
contacting the substrate with a first metal halide precursor; and
contacting the substrate with a nitrogen precursor; and
performing one or more phosphide sub-cycles, each of the one or more phosphide sub-cycles comprising;
contacting the substrate with a phosphorus precursor;
wherein the metal, phosphorus, and nitrogen layer structure comprises one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

8. The atomic layer deposition process of claim 7, wherein the atomic layer deposition process is a super-cycle deposition process comprising performing one or more deposition super-cycles, each deposition super-cycle comprising one or more nitride sub-cycles and one or more phosphide sub-cycles.

9. The atomic layer deposition process of claim 7, wherein the metal, phosphorus, and nitrogen layer structure comprises one or more metal phosphorus nitride layers.

10. The atomic layer deposition process of claim 7, wherein each one of the phosphide sub-cycles further comprises contacting the substrate with a second metal halide precursor.

11. The atomic layer deposition process of claim 8, wherein each of the one or more deposition super-cycle comprises initially performing one or more nitride sub-cycles and subsequently performing one or more metal phosphide sub-cycles.

12. The atomic layer deposition process of claim 11, wherein the metal, phosphorus, and nitrogen layer structure comprises a metal nitride-metal phosphide laminate structure comprising a repeating unit layer structure comprising a metal nitride layer and a metal phosphide layer, the metal phosphide layer being disposed directly on the metal nitride layer.

13. The atomic layer deposition process of claim 10, wherein the first metal halide precursor comprises a first metal species (M₁) and the second metal halide precursor comprises a second metal species (M₂) different to the first metal species.

14. The atomic layer deposition process of claim 7, wherein the phosphorus precursor comprises an alkylphosphine, having the formula RₓPH₃₋ₓ, where x ranges from zero to 3 and R is an alkyl selected from the group consisting of ethyl, methyl, butyl, and propyl.

15. The atomic layer deposition process of claim 14, wherein the alkylphosphine is selected from the group consisting of diethylphosphine, triethylphosphine, dimethylphosphine, trimethylphosphine, and mixtures thereof.

16. The atomic layer deposition process of claim 7, wherein the sub-cycle ratio (N₁:N₂) of the number (N₁) of repetitions of the nitride sub-cycle relative to the number (N₂) of repetitions of the phosphide sub-cycle is varied to control the composition of the metal, phosphorus, and nitrogen layer structure, the sub-cycle ratio (N₁:N₂) being equal to or greater than 1:1.

17. The atomic layer deposition process of claim 7, wherein the metal, phosphorus, and nitrogen layer structure is deposited at a substrate temperature between 250° C. and 400° C.

18. A method of forming at least a portion of a gate stack for a semiconductor device structure, the method comprising:
seating a substrate within a reaction chamber, the substrate comprising a plurality of partially fabricated device structures, wherein one or more of the partially fabricated device structures includes a surface layer comprising a high-k dielectric layer or a silicon oxide surface; and
performing one or more deposition super-cycles of an atomic layer deposition process to deposit a metal, phosphorus, and nitrogen layer structure directly on a surface of the high-k dielectric layer or the silicon oxide surface;
wherein the metal, phosphorus, and nitrogen layer structure comprises a threshold voltage shifting layer and the metal, phosphorus, and nitrogen layer structure comprises one or more metals selected from the group consisting of magnesium (Mg), lanthanum (La), yttrium (Y), aluminum (Al), manganese (Mn), zirconium (Zr), tantalum (Ta), vanadium (V), zinc (Zn), titanium (Ti), niobium (Nb), tin (Sn), tungsten (W), molybdenum (Mo), ruthenium (Ru), antimony (Sb), cobalt (Co), or an alloy thereof.

19. The method of claim 18, wherein one or more the deposition super-cycles comprises:
performing one or more nitride sub-cycles, each of the one or more nitride sub-cycles comprising:
contacting the substrate with a first metal halide precursor; and
contacting the substrate with a nitrogen precursor; and
performing one or more phosphide sub-cycles, each of the one or more phosphide sub-cycles comprising;
contacting the substrate with a second metal precursor; and
contacting the substrate with a phosphorus precursor.

20. The method of claim 19, wherein the threshold voltage shifting layer comprises a metal nitride-metal phosphide laminate structure selected from the group consisting of a titanium nitride-titanium phosphide laminate structure, a molybdenum nitride-molybdenum phosphide laminate structure, and a cobalt nitride-cobalt phosphide laminate structure.
